(19) United States
(12) Patent Application Publication
(10) Pub. No.: US 2024/0327758 A1
(43) Pub. Date: Oct. 3, 2024

(54) COMPOSITION FOR SURFACE TREATMENT, SURFACE TREATMENT METHOD, AND METHOD FOR PRODUCING SEMICONDUCTOR SUBSTRATE

(71) Applicant: FUJIMI INCORPORATED, Kiyosu-shi (JP)

(72) Inventors: Takahito NAGANO, Kiyosu-shi (JP); Tsutomu YOSHINO, Kiyosu-shi (JP); Masafumi NISHIUMI, Kiyosu-shi (JP)

(73) Assignee: FUJIMI INCORPORATED, Kiyosu-shi (JP)

(21) Appl. No.: 18/602,212

(22) Filed: Mar. 12, 2024

(30) Foreign Application Priority Data
Mar. 29, 2023 (JP) 2023-052687
Jul. 19, 2023 (JP) 2023-117307
Feb. 14, 2024 (JP) 2024-020006

(51) Int. Cl. C11D 3/28; C11D 1/00; C11D 3/04; C11D 3/20; C11D 3/37; H01L 21/02; H01L 21/3105

(52) U.S. Cl. CPC C11D 3/28; C11D 1/008; C11D 3/04; C11D 3/2079; C11D 3/3753; H01L 21/02065; H01L 21/31053

(57) ABSTRACT

Provided is a means for allowing residues remaining on the surface of a polished object to be further reduced. Provided is a composition for surface treatment containing components (A) to (C) below and having pH of more than 7.0: the component (A): a piperazine-based compound represented by a formula (a) below and having two or more amino groups having pKa larger than the pH of the composition for surface treatment, the component (B): an anionic polymer, and the component (C): a buffer represented by a formula: A-COO—NH₄⁺ (A is an alkyl group having 1 or more and 10 or less carbon atoms or a phenyl group).

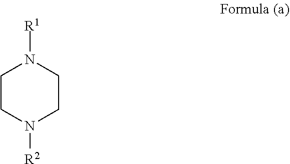

### CROSS-REFERENCE TO RELATED APPLICATION

The entire disclosures of Japanese Patent Application No. 2023-52687 filed on Mar. 29, 2023, Japanese Patent Application No. 2023-117307 filed on Jul. 19, 2023, and Japanese Patent Application No. 2024-020006 filed on Feb. 14, 2024, are incorporated herein by reference in its entirety.

### BACKGROUND

### 1. Technical Field

The present invention relates to a composition for surface treatment, a surface treatment method, and a method for producing a semiconductor substrate.

### 2. Description of Related Arts

In recent years, a so-called chemical mechanical polishing (CMP) technique for physically polishing and flattening a semiconductor substrate in producing a device has been utilized in association with multilayer wiring on the surface of a semiconductor substrate. CMP is a method for flattening a surface of an object to be polished (polishing target) such as a semiconductor substrate, using a polishing composition (slurry) containing abrasive grains such as of silica, alumina, or ceria, an anti-corrosion agent, and a surfactant, and the like. The object to be polished (polishing target) is a wiring, a plug, and the like made of silicon, polysilicon, silicon oxide, silicon nitride, metal and the like.

A large amount of impurities (also referred to as foreign materials or residues) remain on a surface of a semiconductor substrate after CMP procedure. The impurities include abrasive grains, a metal, an anti-corrosion agent, and an organic material such as a surfactant, which are derived from a polishing composition used for CMP, a silicon-containing material or a metal, which are generated by polishing a silicon-containing material, a metal wiring, or a plug or the like as an object to be polished; and further, an organic material such as pad debris generated from various pads and the like.

When a surface of a semiconductor substrate is contaminated with such impurities, this may negatively affect the electrical properties of a semiconductor and may result in a lower device reliability. Therefore, it is desirable to introduce a cleaning step after a CMP step to remove these impurities from the surface of the semiconductor substrate.

As such a cleaning composition, for example, JP 2015-189899 A (corresponding to US 2017/0175053 A1) discloses a polishing composition containing an organic compound containing a specific atom and having a molecular weight of 100 or more, a pH adjusting agent, and 0 to 1% by mass of abrasive grains.

### SUMMARY

According to the polishing composition disclosed in JP 2015-189899 A (corresponding to US 2017/0175053 A1), impurities remaining on the surface of an object to be polished after CMP can be sufficiently removed. However, along with an increase in quality required for a semiconductor substrate, there is required a technique for allowing foreign materials (such as abrasive grain residues and organic residues) on the surface of a semiconductor substrate to be further reduced.

Therefore, the present invention has been made in view of the above circumstances, and an object thereof is to provide a means for allowing residues remaining on a surface of a polished object to be further reduced.

The present inventors have intensively studied to solve the above problem. As a result, the present inventors have found that the above problem can be solved by an alkaline composition for surface treatment containing a piperazine-based compound having a specific structure, an anionic polymer, and ammonium monocarboxylate acting as a buffer, thereby completing the present invention.

That is, the above object is achieved by a surface treatment composition containing components (A) to (C) below, and having pH of more than 7.0:
the component (A): a piperazine-based compound represented by a formula (a) below and having two or more amino groups having pKa larger than the pH of the composition for surface treatment:

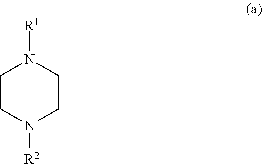

wherein R¹ is a hydrogen atom, or an alkyl group having 1 or more and 10 or less carbon atoms optionally substituted with any of a primary, secondary, and tertiary amino group; and R² is an alkyl group having 1 or more and 10 or less carbon atoms optionally substituted with any of a primary, secondary, and tertiary amino group,
the component (B): an anionic polymer, and
the component (C): a buffer represented by the formula: A-COO—NH₄⁺ (A is an alkyl group having 1 or more and 10 or less carbon atoms or a phenyl group).

### DETAILED DESCRIPTION

The present invention provides a composition for surface treatment containing a component (A), a component (B) and a component (C), and having pH of more than 7.0:
the component (A): a piperazine-based compound represented by the following formula (a) and having two or more amino groups having pKa larger than the pH of the composition for surface treatment,

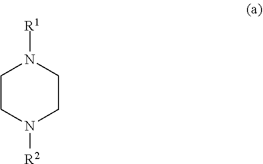

wherein R¹ is a hydrogen atom, or an alkyl group having 1 or more and 10 or less carbon atoms optionally substituted with any of a primary, secondary, and tertiary amino group; and R² is an alkyl group having 1 or more and 10 or less carbon atoms optionally substituted with any of a primary, secondary, and tertiary amino group,
the component (B): an anionic polymer, and
the component (C): a buffer represented by a formula: A-COO—NH₄⁺ (A is an alkyl group having 1 or more and 10 or less carbon atoms or a phenyl group).

According to the present invention, residues remaining on a surface of a polished object may further be reduced.

Hereinafter, the composition for surface treatment having the above constitution may also be referred to as “composition for surface treatment according to the present invention” or “composition for surface treatment according to one embodiment of the present invention”. As used herein, the “amino group having pKa larger than the pH of the composition for surface treatment” may also be referred to as “amino group having a large pKa” or “amino group having a large pKa according to the present invention”.

According to such a composition for surface treatment according to the present invention, residues (e.g., abrasive grain residues and organic residues) remaining on a surface of a polished object (in particular, a polished substrate having a nitrogen-silicon bond or containing silicon oxide) can be further efficiently reduced.

The present inventors presume a mechanism in which by such a constitution, residues on a surface of a polished object can be efficiently removed, as follows.

The composition for surface treatment according to the present invention contains the specific components (A) to (C). Among these components, the component (A) is represented by the above formula (a), and has a plurality of (two or more) amino groups having pKa larger than the pH of the composition for surface treatment (amino groups having a large pKa). Since the amino groups having a large pKa as the component (A) have a larger pKa than the pH of the composition for surface treatment, the amino groups are easily dissociated in the composition for surface treatment (receive hydrogen ions) and more positively charged. A surface of a polished object (in particular, the polished substrate having a nitrogen-silicon bond or containing silicon oxide) is negatively charged under alkaline conditions. Thus, the component (A) interacts with (is adsorbed to) the surface of the polished object (in particular, aa polished substrate having a nitrogen-silicon bond or containing silicon oxide), and acts like a so-called protective film. Herein, ammonium monocarboxylate contained as the component (C) (in particular, monocarboxylic acid anion contained in the component (C)) is presumed to promote the adsorption of the component (A) (the formation of a protective film) on a surface of a polished object (in particular, a polished substrate having a nitrogen-silicon bond or containing silicon oxide) by the interaction with the component (A).

In addition, the component (B) is anionic (that is, negatively charged in the composition for surface treatment). Thus, amino group (s) that have not interacted with (have not been adsorbed to) a polished object among the amino groups in the component (A) also interact with (are also adsorbed to) the component (B). That is, the positively charged amino groups having a large pKa of the component (A) interact with both the negatively charged surface of a polished object and the component (B), and the component (B) is firmly adsorbed on a polished object via the component (A) and acts as a protective film (steric repulsion layer) on a polished object. In addition, since the component (B) is negatively charged, it shifts the zeta potential of a polished object (in particular, a polished substrate having a nitrogen-silicon bond or containing silicon oxide) to a more negative side. Consequently, electrostatic repulsion between a polished object (in particular, a polished substrate having a nitrogen-silicon bond or containing silicon oxide) and the component (B) further increases. Thus, according to the composition for surface treatment according to the present invention, residues can be efficiently removed.

The above mechanism is based on a presumption, and the present invention should not be limited by the above mechanism in any way.

Hereinafter, preferred embodiments of the present invention will be described. The present invention is not limited only to the following embodiments, and various modification can be made within the scope of the claims. In addition, the embodiments described herein can be other embodiments by arbitrary combination.

Throughout the present description, any expression in a singular form should be understood to encompass the concept of its plural form, unless otherwise stated. Thus, the article specifying a single form (e.g., “a”, “an”, “the”, and the like in the case of English language) should be understood to encompass the concept of its plural form, unless otherwise stated. Further, unless particularly stated otherwise, any term used in the present description should be understood as a term that is used to have the meaning conventionally used in the relevant technical field. Therefore, unless defined otherwise, all the technical terms and scientific terms used in the present description have the same meaning as generally understood by a person ordinarily skilled in the art to which the present invention is pertained. If there is any conflict in meaning, the present description (including the definitions) takes priority.

As used herein, the term “(meth)acryl” encompasses both acryl and methacryl. Thus, for example, the term “(meth)acrylic acid” encompasses both acrylic acid and methacrylic acid.

As used herein, “X to Y” indicating a range includes X and Y and means “X or more and Y or less”. As used herein, “A and/or B” means at least one of A and B, and encompasses both A and B, or either one of A or B. Unless otherwise indicated, the operation and the measurement of physical properties and the like are performed under the conditions of room temperature (20 to 25° C.)/relative humidity of 40 to 50% RH.

### [Residue(s)]

As used herein, residues refer to foreign material (s) attached to a surface of a polished object. Examples of the residues include, but are not particularly limited to, residues derived from an object to be polished, organic residues described below, particle residues derived from abrasive grains (abrasive grain residues) contained in a polishing composition, residues including components other than particle residues and organic residues, and other residues such as a mixture of particle residues and organic residues. Among these, according to the composition for surface treatment according to the present invention, abrasive grain residues (particle residues) and organic residues can be particularly efficiently removed. That is, in one embodiment of the present invention, the residue includes at least one of a abrasive grain residue (particle residues) and an organic residue.

A total number of residues represents a total number of all residues regardless of the type of the residue. The total number of residues can be measured by using a wafer defect inspection apparatus. In addition, the number of residues represents a total number of specific residues. The details of the method for measuring the number of residues will be described in Examples described below.

As used herein, the term “organic residue” represents components including organic materials such as organic low molecular compounds and organic polymer compounds, organic salts, and the like, among the foreign materials adhered to a surface of a polished object (object to be subjected to surface treatment).

Examples of the organic residue adhered to a polished object may include pad debris generated from a pad used in a polishing step or a rinse polishing step described below, components derived from an additive(s) contained in a polishing composition used in a polishing step or a composition for surface treatment used in a rinse polishing step, and the like.

Since the organic residue and other foreign materials are greatly different in color and shape, whether the foreign material is an organic residue or not can be visually determined by scanning electron microscopy (SEM) observation. In addition, whether the foreign material is an organic residue or not may be determined by elemental analysis with an energy dispersive X-ray spectrometer (EDX), if necessary. The number of organic residues can be measured by using a wafer defect inspection apparatus, and by SEM or EDX elemental analysis.

### [Polished Object]

As used herein, the term “polished object” means a polished object after being polished in a polishing step. The polishing step is not particularly limited, and is preferably a CMP step.

A material contained in the polished object according to the present invention is a Si-based material, but is not particularly limited thereto. From the viewpoint of further promoting the formation of a protective film (steric repulsion layer) by the adsorption of the component (A) and the component (B), in particular, the component (B), and more significantly obtaining the effect (s) of the present invention, it is preferable that a polished object be a substrate (polished object) containing a material having a nitrogen-silicon bond, such as silicon nitride (Si₃N₄), it is more preferable to subject a surface (a layer, or a film) containing a material having a nitrogen-silicon bond, such as silicon nitride (Si₃N₄) to surface treatment using the composition for surface treatment according to the present invention, and it is particularly preferable to subject a surface (a layer, or a film) composed of a material having a nitrogen-silicon bond, such as silicon nitride (Si₃N₄) to surface treatment using the composition for surface treatment according to the present invention. A polished object may be made of a plurality of materials.

Additionally, from the viewpoint of further promoting the formation of a protective film (steric repulsion layer) by the adsorption of the component (A) and the component (B), in particular, the component (B), and more significantly obtaining the effect(s) of the present invention, it is preferable that a polished object be a substrate (polished object) containing silicon oxide (SiO₂), it is more preferable to subject TEOS type silicon oxide film (hereinafter, also simply referred to as “TEOS” or “TEOS film”) formed using tetraethyl orthosilicate as a precursor, HDP (High-density Plasma) film (layer), USG (Undoped Silicate Glass) film (layer), PSG (Phosphorus Silicate Glass) film (layer), BPSG (Boron-Phospho Silicate Glass) film (layer), or RTO (Rapid Thermal Oxidation) film (layer) to surface treatment using the composition for surface treatment according to the present invention, and it is particularly preferable to subject TEOS type silicon oxide film (layer) to surface treatment using the composition for surface treatment according to the present invention. A polished object may be made of a plurality of materials.

### [Composition for Surface Treatment]

The composition for surface treatment according to the present invention can be used to reduce residues (in particular, abrasive grain residues and organic residues) on a surface of a polished object.

In the present description, the piperazine-based compound as the component (A) is simply referred to as the “piperazine-based compound according to the present invention” or the “piperazine-based compound”. In addition, the “amino group having pKa larger than the pH of the composition for surface treatment” is also referred to as the “amino group having a large pKa” or the “amino group having a large pKa according to the present invention”. The anionic polymer as the component (B) is also simply referred to as the “anionic polymer according to the present invention” or the “anionic polymer”. The buffer represented by the formula: A-COO—NH₄⁺ (A is an alkyl group having 1 or more and 10 or less carbon atoms or a phenyl group) as the component (C) is also simply referred to as the “buffer according to the present invention” or “ammonium monocarboxylate according to the present invention” or “ammonium monocarboxylate”.

### <Component (A)>

The composition for surface treatment according to the present invention contains a piperazine-based compound represented by the following formula (a) and having two or more amino groups having pKa (acid dissociation constant) larger than the pH of the composition for surface treatment, as the component (A).

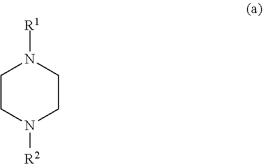

In the above formula (a), R¹ represents a hydrogen atom, or an alkyl group having 1 or more and 10 or less carbon atoms optionally substituted with any of a primary, secondary, and tertiary amino group. R² is an alkyl group having 1 or more and 10 or less carbon atoms optionally substituted with any of a primary, secondary, and tertiary amino group.

In the above formula (a), R¹ and R² may be the same or different from each other. The alkyl groups having 1 or more and 10 or less carbon atoms as R¹ and R² may be linear, branched, or cyclic.

Specific examples of a linear alkyl group may include a methyl group, an ethyl group, an n-propyl group, an n-butyl group, an n-pentyl group, an n-hexyl group, an n-heptyl group, an n-octyl group, an n-nonyl group, and an n-decyl group.

Specific examples of a branched alkyl group may include an isopropyl group, an isobutyl group, a sec-butyl group, a tert-butyl group, an isopentyl group, a tert-pentyl group, a neopentyl group, a 1,2-dimethylpropyl group, an isohexyl group, a 1,3-dimethylbutyl group, a 1-isopropylpropyl group, a 1,2-dimethylbutyl group, a 1,4-dimethylpentyl group, a 3-ethylpentyl group, a 2-methyl-1-isopropylpropyl group, a 1-ethyl-3-methylbutyl group, a 2-ethylhexyl group, a 3-methyl-1-isopropylbutyl group, a 2-methyl-1-isopropyl group, a 1-tert-butyl-2-methylpropyl group, and an isodecyl group.

Specific examples of a cyclic (cycloaliphatic) alkyl group may include cycloalkyl groups having 3 or more and 10 or less carbon atoms, such as a cyclopropyl group, a cyclobutyl group, a cyclopentyl group, and a cyclohexyl group.

Among them, the alkyl groups as R¹ and R² are preferably linear or branched, and more preferably linear.

An upper limit of the number of carbon atoms in the above alkyl group is preferably 8 or less, more preferably 6 or less, still more preferably 5 or less, and particularly preferably 3 or less, from the viewpoint of further improving the effect of reducing residues. On the other hand, a lower limit of the number of carbon atoms in the above alkyl group is preferably 2 or more. Thus, as one example, the number of carbon atoms in the alkyl group as R¹ and R² is preferably 1 or more and 8 or less, more preferably 1 or more and 6 or less, still more preferably 1 or more and 5 or less, still much more preferably 1 or more and 3 or less, particularly preferably 2 or 3, and most preferably 3.

The above alkyl groups may be substituted with at least one amino group of a primary amino group, a secondary amino group, and a tertiary amino group, or may be unsubstituted. As used herein, the term “primary amino group” means —NH₂. Also, the term “secondary amino group” means a functional group (—NHR^{A}; provided that, R^{A} represents an organic group) having one hydrogen atom and one organic group on a nitrogen atom and having a structure in which a bond between one of the carbon atoms constituting the organic group and the above nitrogen atom is a single bond. Also, the term “tertiary amino group” means a functional group (—N(R^{B})(R^{C}); provided that, R^{B} and R^{C} each independently represent an organic group) having two same or different organic groups on a nitrogen atom and having a structure in which each bond between one of the carbon atoms constituting each organic group and the above nitrogen atom is a single bond. The organic groups as R^{A} constituting the above secondary amino group (—NHR^{A}) and as R^{B} and R^{C} constituting the above tertiary amino group (—N(R^{B})(R^{C})) mean groups containing a carbon atom.

The above R^{A}, R^{B}, and R^{C} are preferably each independently a hydrocarbon group, more preferably an alkyl group or an aryl group, and more preferably an alkyl group.

The number of carbon atoms of the alkyl group as the above R^{A}, R^{B}, and R^{C} is not particularly limited, and preferably 1 or more and 10 or less, from the viewpoint that the removability of the component (A) itself is excellent. Herein, the alkyl group having 1 or more and 10 or less carbon atoms may be linear, branched, or cyclic. Specific examples of such alkyl groups are the same as those specifically exemplified as the above alkyl groups as R¹ and R².

Examples of the above secondary amino group having the alkyl group include alkylamino groups having 1 or more and 10 or less carbon atoms, such as a methylamino group, an ethylamino group, an n-propylamino group, an n-butylamino group, an isobutylamino group, an n-hexylamino group, an n-heptylamino group, an n-octylamino group, an n-nonylamino group, and an n-decylamino group. Examples of the above tertiary amino group having the alkyl group include dialkylamino groups having 2 or more and 20 or less carbon atoms, such as a dimethylamino group, a diethylamino group, a di-n-propylamino group, a di-n-butylamino group, and a methylethylamino group.

When the alkyl group as R¹ and R² is substituted with any of primary to tertiary amino groups in the above formula (a), the alkyl groups are preferably substituted with a primary amino group or a tertiary amino group, and more preferably substituted with a primary amino group. According to the above embodiment, the residues can be further effectively reduced.

More specifically, when the alkyl group as R¹ and R² is substituted with any of primary to tertiary amino groups, the alkyl group is preferably a methyl group substituted with a primary amino group (—NH₂), an ethyl group substituted with a primary amino group (—NH₂), an n-propyl group substituted with a primary amino group (—NH₂), a methyl group substituted with a dimethylamino group, an ethyl group substituted with a dimethylamino group, or an n-propyl group substituted with a dimethylamino group, more preferably an ethyl group substituted with a primary amino group (—NH₂), an n-propyl group substituted with a primary amino group (—NH₂), or an ethyl group substituted with a dimethylamino group, still more preferably an ethyl group substituted with a primary amino group (—NH₂) or an n-propyl group substituted with a primary amino group (—NH₂), and particularly preferably an n-propyl group substituted with a primary amino group (—NH₂).

In the above formula (a), at least one of R¹ and R² is an alkyl group substituted with any of primary to tertiary amino groups. It is preferable that R¹ be a hydrogen atom and R² be an alkyl group substituted with any of primary to tertiary amino groups, or both R¹ and R² be alkyl groups substituted with any of primary to tertiary amino groups, more preferable that R¹ be a hydrogen atom and R² be an alkyl group substituted with a primary amino group, or both R¹ and R² be alkyl groups substituted with a primary or tertiary amino group, and particularly preferable that R¹ be a hydrogen atom and R² be an alkyl group substituted with a primary amino group, or both R¹ and R² be alkyl groups substituted with a primary amino group. According to the above embodiment, the residues can be further effectively reduced.

Specific examples of the piperazine-based compound represented by the formula (a) include 1-methylpiperazine, 1-ethylpiperazine, 1-propylpiperazine, aminomethylpiperazine, aminoethylpiperazine, aminopropylpiperazine, 1-(2-dimethylaminoethyl)-4-methylpiperazine, 1-(2-dimethylaminoethyl)-4-ethylpiperazine, 1-(2-dimethylaminoethyl)-4-propylpiperazine, 1-(2-diethylaminoethyl)-4-methylpiperazine, 1-(2-diethylaminoethyl)-4-ethylpiperazine, 1-(2-diethylaminoethyl)-4-propylpiperazine, 1,4-bis(3-aminomethyl)piperazine, 1,4-bis(3-aminoethyl)piperazine, and 1,4-bis(3-aminopropyl)piperazine.

The piperazine-based compound as the component (A) has two or more amino groups having pKa larger than the pH of the composition for surface treatment (amino groups having a large pKa). Here, when the number of amino groups having a large pKa present in the piperazine-based compound according to the present invention is one or no amino group having a large pKa is present therein, the piperazine-based compound can interact with only one of the surface of the polished object and the component (B) or with neither of them. Consequently, a protective film (steric repulsion layer) to be formed by the adsorption of the component (B) cannot be sufficiently formed on the surface of the polished object, and as a result, the residues cannot be sufficiently removed. From the viewpoint of further improving the effect of reducing residues, the number of amino groups having a large pKa present in the piperazine-based compound according to the present invention is preferably 2 or more and 5 or less, more preferably 2 or more and 4 or less, still more preferably 2 or 3, and particularly preferably 2.

The difference between the pKa in the piperazine-based compound as the component (A) and the pH of the composition for surface treatment is preferably as large as possible, in terms of further improving the effect of reducing residues. Specifically, the difference between the maximum pKa in the pKa's of the amino groups present in the piperazine-based compound (the maximum pKa) and the pH of the composition for surface treatment (=the maximum pKa−pH) is, for example, 0.5 or more, preferably 0.6 or more, more preferably 1.0 or more, still more preferably more than 1.30, still much more preferably 1.50 or more, particularly preferably 1.60 or more, and most preferably 2.00 or more. Since the difference between the maximum pKa in the pKa's of the amino groups present in the piperazine-based compound (the maximum pKa) and the pH of the composition for surface treatment (=the maximum pKa−pH) is preferably as large as possible, the upper limit of the above difference is not particularly limited, and for example, 4.0 or less, preferably 3.5 or less, and more preferably 3.0 or less.

The pKa (acid dissociation constant) is a numerical value calculated from the concentration of each component of the piperazine-based compound in acid dissociation equilibrium at 25° C. in water, and specifically, is a numerical value expressed as a common logarithm of a numerical value Ka calculated from the following formula.

$$\\ HA ⇆ {H}^{{}_{} +} + {A}^{{}_{} -}$$

$$\\ Ka = \frac{[ {H}^{{}_{} +} ] + [ {A}^{{}_{} -} ]}{[ HA ]}$$

In the present description, the pKa (acid dissociation constant) of the amino group present in the piperazine-based compound is calculated using ChemSketch which is a structural formula drawing software. Specifically, the structural formula of each compound was drawn, and pKa is automatically calculated from the structure.

In the present description, the maximum value in the pKa of each amino group measured above is employed as the maximum pKa in the pKa's of the amino groups present in the piperazine-based compound (the maximum pKa).

From the viewpoint of further improving the effect of reducing residues, it is preferable that the component (A) be only a piperazine-based compound represented by the above formula (a) and having two or more amino groups having pKa larger than the pH of the composition for surface treatment (the piperazine-based compound according to the present invention).

That is, it is preferable that the component (A) contain a piperazine-based compound represented by the above formula (a) in which R¹ is a hydrogen atom, or an alkyl group (in particular, linear alkyl group) having 1 or more and 5 or less carbon atoms optionally substituted with a primary or tertiary amino group; and R² is an alkyl group (in particular, linear alkyl group) having 1 or more and 5 or less carbon atoms optionally substituted with a primary or tertiary amino group. In the embodiment, it is more preferable that the component (A) be only a piperazine-based compound represented by the above formula (a) in which R¹ is a hydrogen atom, or an alkyl group (in particular, linear alkyl group) having 1 or more and 5 or less carbon atoms optionally substituted with a primary or tertiary amino group; and R² is an alkyl group (in particular, linear alkyl group) having 1 or more and 5 or less carbon atoms optionally substituted with a primary or tertiary amino group.

It is preferable that the component (A) contain a piperazine-based compound represented by the above formula (a) in which R¹ is a hydrogen atom, or an alkyl group (in particular, linear alkyl group) having 1 or more and 5 or less carbon atoms optionally substituted with a primary or tertiary amino group; and R² is an alkyl group (in particular, linear alkyl group) having 1 or more and 5 or less carbon atoms substituted with a primary or tertiary amino group. In the embodiment, it is more preferable that the component (A) be only a piperazine-based compound represented by the above formula (a) in which R¹ is a hydrogen atom, or an alkyl group (in particular, linear alkyl group) having 1 or more and 5 or less carbon atoms optionally substituted with a primary or tertiary amino group; and R² is an alkyl group (in particular, linear alkyl group) having 1 or more and 5 or less carbon atoms substituted with a primary or tertiary amino group.

It is particularly preferable that the component (A) contain a piperazine-based compound represented by the above formula (a) in which R¹ is a hydrogen atom, or an alkyl group (in particular, linear alkyl group) having 1 or more and 3 or less carbon atoms optionally substituted with a primary or tertiary amino group; and R² is an alkyl group (in particular, linear alkyl group) having 1 or more and 3 or less carbon atoms substituted with a primary amino group. In the embodiment, it is more preferable that the component (A) be only a piperazine-based compound represented by the above formula (a) in which R¹ is a hydrogen atom, or an alkyl group (in particular, linear alkyl group) having 1 or more and 3 or less carbon atoms optionally substituted with a primary or tertiary amino group; and R² is an alkyl group (in particular, linear alkyl group) having 1 or more and 3 or less carbon atoms substituted with a primary amino group.

It is most preferable that the component (A) contain a piperazine-based compound represented by the above formula (a) in which R¹ and R² are each independently an alkyl group (in particular, linear alkyl group) having 1 or more and 3 or less carbon atoms substituted with a primary amino group. In the embodiment, it is most preferable that the component (A) be only a piperazine-based compound represented by the above formula (a) in which R¹ and R² are each independently an alkyl group (in particular, linear alkyl group) having 1 or more and 3 or less carbon atoms substituted with a primary amino group.

The piperazine-based compound that may be used as the component (A) may be produced by synthesis, or may be a commercial product. The piperazine-based compound as the component (A) may be used alone or in combination of two or more.

A content of the component (A) in the composition for surface treatment is appropriately set according to the type and the desired effect(s) of the component (A) to be used. The content of the component (A) is preferably 0.001% by mass or more, more preferably 0.005% by mass or more, still more preferably 0.01% by mass or more, still much more preferably 0.03% by mass or more, still more preferably 0.10% by mass or more, still much more preferably more than 0.25% by mass, particularly preferably 0.30% by mass or more, and most preferably 0.50% by mass or more, relative to 100% by mass of the total mass of the composition for surface treatment (based on the composition for surface treatment). With such a lower limit value, the component (A) further effectively improves the interaction (adsorption) of the component (B) with (to) the polished object (in particular, the polished substrate having a nitrogen-silicon bond or containing silicon oxide), and can form a protective film (steric repulsion layer). Consequently, residues can be further efficiently removed. The upper limit of the content of the component (A) in the composition for surface treatment is preferably 2.0% by mass or less, more preferably 1.5% by mass or less, still more preferably 1.2% by mass or less, and particularly preferably 1.10% by mass or less, relative to 100% by mass of the total mass of the composition for surface treatment (based on the composition for surface treatment). With such an upper limit value, the component (A) itself is suppressed to become residues, and residues can be efficiently removed. In one embodiment of the present invention, the content of the component (A) is 0.001% by mass or more and 2.0% by mass or less, relative to 100% by mass of the total mass of the composition for surface treatment (based on the composition for surface treatment). In one embodiment of the present invention, the content of the component (A) is 0.005% by mass or more and 1.5% by mass or less, relative to 100% by mass of the total mass of the composition for surface treatment (based on the composition for surface treatment). In one embodiment of the present invention, the content of the component (A) is 0.01% by mass or more and 1.2% by mass or less, relative to 100% by mass of the total mass of the composition for surface treatment (based on the composition for surface treatment). In one embodiment of the present invention, the content of the component (A) is 0.03% by mass or more and less than 1.2% by mass, relative to 100% by mass of the total mass of the composition for surface treatment (based on the composition for surface treatment). In one embodiment of the present invention, the content of the component (A) is 0.10% by mass or more and 1.2% by mass or less, relative to 100% by mass of the total mass of the composition for surface treatment (based on the composition for surface treatment). In one embodiment of the present invention, the content of the component (A) is more than 0.25% by mass and 1.2% by mass or less, relative to 100% by mass of the total mass of the composition for surface treatment (based on the composition for surface treatment). In one embodiment of the present invention, the content of the component (A) is 0.30% by mass or more and 1.2% by mass or less, relative to 100% by mass of the total mass of the composition for surface treatment (based on the composition for surface treatment). In one embodiment of the present invention, the content of the component (A) is 0.50% by mass or more and 1.10% by mass or less, relative to 100% by mass of the total mass of the composition for surface treatment (based on the composition for surface treatment). When the composition for surface treatment contains two or more components (A), the content of the component (A) means the total amount thereof.

### <Component (B)>

The composition for surface treatment according to the present invention contains an anionic polymer as the component (B). The “anionic polymer” as used herein refers to a polymer having an anionic group such as a carboxylic acid group, a sulfonic acid group, or a phosphate group, or a salt thereof in its molecule.

The anionic polymer interacts with the above component (A) and adsorbed to the component (A) to form a protective film (steric repulsion layer) on the polished object. In addition, since the component (B) is negatively charged, it shifts the zeta potential of the polished object (in particular, the polished substrate having a nitrogen-silicon bond or containing silicon oxide) to a more negative side. Consequently, electrostatic repulsion between the polished object (in particular, the polished substrate having a nitrogen-silicon bond or containing silicon oxide) and the component (B) further increases. Thus, according to the composition for surface treatment according to the present invention, the removal of the residues on the surface of the polished object can be promoted (attachment and reattachment of abrasive grain residues, organic residues, and the like can be suppressed).

The anionic polymer is a polymer having the same repeating structural unit (homopolymer) or different repeating structural units (copolymer), and may typically be a compound having a weight average molecular weight (Mw) of 1,000 or more. The form of the copolymer in the case where the anionic polymer is a copolymer may be any of a block copolymer, a random copolymer, a graft copolymer, and an alternating copolymer.

Examples of the anionic polymer include polycarboxylic acids such as polyacrylic acid, a polyacrylic acid copolymer, polymethacrylic acid, a polymethacrylic acid copolymer, a poly(acrylic acid-polymethacrylic acid) copolymer, a maleic anhydride copolymer, carboxymethylcellulose, and alginic acid; polysulfonic acids such as polystyrene sulfonic acid, a polystyrene sulfonic acid copolymer, polynaphthalene sulfonic acid, and acrylamide-t-butylsulfonic acid; and poly(carboxylic acid-sulfonic acid) (a copolymer of carboxylic acid and sulfonic acid), and salts thereof. In addition, not only a polymer having such a main chain structure, but also a graft copolymer having an anionic polymer structure in a side chain can be preferably used.

When the anionic polymer is in a salt form, examples thereof include alkali metal salts such as lithium salt, sodium salt, potassium salt, rubidium salt, and cesium salt, and Group 2 element salts such as magnesium salt, calcium salt, strontium salt, and barium salt, of polycarboxylic acid, polysulfonic acid, and poly(carboxylic acid-sulfonic acid).

These anionic polymers may be used alone or in combination of two or more.

Among these, from the viewpoint of further improving the effect of removing residues, the anionic polymer preferably has a carboxylic acid group, a sulfonic acid group, or a salt thereof, more preferably a carboxylic acid group or a sulfonic acid group, or an alkali metal salt thereof, still more preferably a carboxylic acid group or a sulfonic acid group, and particularly preferably a carboxylic acid group.

A compound other than the above anionic polymer (anionic polymer according to the present invention) may be contained as the component (B). From the viewpoint of further improving the effect of reducing residues, it is preferable that the component (B) be only the above anionic polymer (anionic polymer according to the present invention).

That is, it is preferable that the component (B) contain at least one anionic polymer selected from the group consisting of poly(meth)acrylic acid, polystyrene sulfonic acid and poly(carboxylic acid-sulfonic acid) (a copolymer of carboxylic acid and sulfonic acid), and salts thereof. In the embodiment, it is more preferable that the component (B) be only at least one anionic polymer selected from the group consisting of poly(meth)acrylic acid, polystyrene sulfonic acid and poly(carboxylic acid-sulfonic acid) (a copolymer of carboxylic acid and sulfonic acid), and salts thereof.

It is preferable that the component (B) contain at least one anionic polymer selected from the group consisting of poly(meth)acrylic acid and polystyrene sulfonic acid, and salts thereof. In the embodiment, it is more preferable that the component (B) be only at least one anionic polymer selected from the group consisting of poly(meth)acrylic acid, polystyrene sulfonic acid, and salts thereof. The above form is particularly applicable when the polished object contains a material having a nitrogen-silicon bond.

It is preferable that the component (B) contain at least one anionic polymer selected from the group consisting of poly(meth)acrylic acid and polystyrene sulfonic acid, and alkali metal salts thereof. In the embodiment, it is more preferable that the component (B) be only at least one anionic polymer selected from the group consisting of poly(meth)acrylic acid and polystyrene sulfonic acid, and alkali metal salts thereof. The above form is particularly applicable when the polished object contains a material having a nitrogen-silicon bond.

It is preferable that the component (B) contain at least one of poly(meth)acrylic acid and an alkali metal salt thereof. In the embodiment, it is more preferable that the component (B) be only at least one of poly(meth)acrylic acid and an alkali metal salt thereof. The above form is particularly applicable when the polished object contains a material having a nitrogen-silicon bond.

Additionally, it is preferable that the component (B) contain at least one anionic polymer selected from the group consisting of polystyrene sulfonic acid and poly(carboxylic acid-sulfonic acid) (a copolymer of carboxylic acid and sulfonic acid), and salts thereof. In the embodiment, it is more preferable that the component (B) be only at least one anionic polymer selected from the group consisting of polystyrene sulfonic acid and poly(carboxylic acid-sulfonic acid) (a copolymer of carboxylic acid and sulfonic acid), and salts thereof. The above form is particularly applicable when the polished object contains a material containing a silicon oxide.

It is preferable that the component (B) contain at least one anionic polymer selected from the group consisting of polystyrene sulfonic acid and poly(carboxylic acid-sulfonic acid) (a copolymer of carboxylic acid and sulfonic acid), and alkali metal salts thereof. In the embodiment, it is more preferable that the component (B) be only at least one anionic polymer selected from the group consisting of polystyrene sulfonic acid and poly(carboxylic acid-sulfonic acid) (a copolymer of carboxylic acid and sulfonic acid), and alkali metal salts thereof. The above form is particularly applicable when the polished object contains a material containing a silicon oxide.

It is preferable that the component (B) contain at least one anionic polymer selected from the group consisting of polystyrene sulfonic acid and alkali metal salts thereof. In the embodiment, it is more preferable that the component (B) be only at least one anionic polymer selected from the group consisting of polystyrene sulfonic acid and alkali metal salts thereof. The above form is particularly applicable when the polished object contains a material containing a silicon oxide.

A lower limit of a weight average molecular weight (Mw) of the anionic polymer is preferably 1,000 or more, more preferably 2,000 or more, still more preferably 5,000 or more, still much more preferably 10,000 or more, still more preferably 20,000 or more, particularly preferably 200,000 or more, and most preferably more than 200,000. An upper limit of a weight average molecular weight (Mw) of the anionic polymer is preferably 5,000,000 or less, more preferably 3,000,000 or less, particularly preferably 2,000,000 or less, and most preferably 1,500,000 or less. As one example, the weight average molecular weight (Mw) of the anionic polymer is preferably 1,000 or more and 5,000,000 or less, more preferably 2,000 or more and 4,000,000 or less, still more preferably 5,000 or more and 2,000,000 or less, still much more preferably 10,000 or more and 2,000,000 or less, still more preferably 20,000 or more and 2,000,000 or less, particularly preferably 200,000 or more and 2,000,000 or less, and most preferably more than 200,000 and 1,500,000 or less.

The weight average molecular weight (Mw) of the anionic polymer can be measured as a value in terms of polyethylene glycol using gel permeation chromatography (GPC), and the details of the measurement method will be described in Examples described below.

The anionic polymer that may be used as the component (B) may be produced by synthesis, or may be a commercial product. Examples of the commercial product include polyacrylic acid (manufactured by TOAGOSEI CO., LTD.), sodium polystyrene sulfonate (manufactured by Tosoh Finechem Corporation), and a copolymer of carboxylic acid and sulfonic acid (sodium salt) (manufactured by TOAGOSEI CO., LTD.).

The anionic polymer as the component (B) may be used alone or in combination of two or more.

A content of the component (B) in the composition for surface treatment is appropriately set according to the type and the desired effect(s) of the component (B) to be used. The content of the component (B) is preferably 0.0001% by mass or more, more preferably 0.001% by mass or more, still more preferably 0.005% by mass or more, particularly preferably 0.01% by mass or more, and most preferably 0.02% by mass or more, relative to 100% by mass of the total mass of the composition for surface treatment (based on the composition for surface treatment). An upper limit of the content of the component (B) in the composition for surface treatment is preferably 1.0% by mass or less, more preferably 0.5% by mass or less, still more preferably 0.3% by mass or less, and particularly preferably 0.1% by mass or less, relative to 100% by mass of the total mass of the composition for surface treatment (based on the composition for surface treatment). In one embodiment of the present invention, the content of the component (B) is 0.0001% by mass or more and 1.0% by mass or less, relative to 100% by mass of the total mass of the composition for surface treatment (based on the composition for surface treatment). In one embodiment of the present invention, the content of the component (B) is 0.001% by mass or more and 0.5% by mass or less, relative to 100% by mass of the total mass of the composition for surface treatment (based on the composition for surface treatment). In one embodiment of the present invention, the content of the component (B) is 0.005% by mass or more and 0.3% by mass or less, relative to 100% by mass of the total mass of the composition for surface treatment (based on the composition for surface treatment). In one embodiment of the present invention, the content of the component (B) is 0.01% by mass or more and 0.1% by mass or less, relative to 100% by mass of the total mass of the composition for surface treatment (based on the composition for surface treatment). In one embodiment of the present invention, the content of the component (B) is 0.02% by mass or more and 0.1% by mass or less, relative to 100% by mass of the total mass of the composition for surface treatment (based on the composition for surface treatment). When the composition for surface treatment contains two or more components (B), the content of the component (B) means the total amount thereof.

Instead of or in addition to the above, a mixing ratio between the component (A) and the component (B) in the composition for surface treatment is appropriately set according to the type and the desired effect(s) of the component (A) and the component (B) to be used. The mixing ratio of the component (A) to the component (B) (content ratio of the component (A)/the component (B)) (mass ratio) is preferably 0.5 or more, more preferably more than 1, still more preferably 2 or more, still much more preferably more than 2, still more preferably 10 or more, particularly preferably more than 20, and most preferably 25 or more. The mixing ratio of the component (A) to the component (B) (content ratio of the component (A)/the component (B)) (mass ratio) is preferably 110 or less, more preferably 55 or less, still more preferably less than 50, and particularly preferably 30 or less. In one embodiment of the present invention, the mixing ratio of the component (A) to the component (B) (content ratio of the component (A)/the component (B)) (mass ratio) is 0.5 or more and 15 or less. In one embodiment of the present invention, the mixing ratio of the component (A) to the component (B) (content ratio of the component (A)/the component (B)) (mass ratio) is more than 1 and 10 or less. In one embodiment of the present invention, the mixing ratio of the component (A) to the component (B) (content ratio of the component (A)/the component (B)) (mass ratio) is 2 or more and 110 or less. In one embodiment of the present invention, the mixing ratio of the component (A) to the component (B) (content ratio of the component (A)/the component (B)) (mass ratio) is more than 2 and 110 or less. In one embodiment of the present invention, the mixing ratio of the component (A) to the component (B) (content ratio of the component (A)/the component (B)) (mass ratio) is 10 or more and 110 or less. In one embodiment of the present invention, the mixing ratio of the component (A) to the component (B) (content ratio of the component (A)/the component (B)) (mass ratio) is more than 20 and 110 or less. In one embodiment of the present invention, the mixing ratio of the component (A) to the component (B) (content ratio of the component (A)/the component (B)) (mass ratio) is 25 or more and 55 or less. In one embodiment of the present invention, the mixing ratio of the component (A) to the component (B) (content ratio of the component (A)/the component (B)) (mass ratio) is 25 or more and less than 50. In one embodiment of the present invention, the mixing ratio of the component (A) to the component (B) (content ratio of the component (A)/the component (B)) (mass ratio) is 25 or more and 30 or less. When the composition for surface treatment contains two or more components (A), the content of the component (A) means the total amount thereof. Also, when the composition for surface treatment contains two or more components (B), the content of the component (B) means the total amount thereof.

### <Component (C)>

The composition for surface treatment according to the present invention contains the component (C) in addition to the above components (A) and (B). The component (C) contains a buffer represented by the formula: A-COO—NH₄⁺ (ammonium monocarboxylate). As used herein, the term “buffer” means a substance imparting a buffering action to the composition for surface treatment (solution) in order to keep the pH constant.

Although the component (C) may contain a component (e.g., a known buffer) other than the buffer represented by the above formula: A-COO—NH₄⁺, the component (C) is preferably composed of a buffer represented by the above formula: A-COO—NH₄⁺ (the component (C) is a buffer represented by the above formula: A-COO—NH₄⁺), from the viewpoint of further improving the effect(s) by the present invention. With the presence of the component (C), the residues remaining on the surface of a polished object may be efficiently removed. That is, in a preferred embodiment of the present invention, the component (C) is composed of a buffer represented by the above formula: A-COO—NH₄⁺ (the component (C) is a buffer represented by the above formula: A-COO—NH₄⁺).

In the above formula: A-COO—NH₄⁺, A is an alkyl group having 1 or more and 10 or less carbon atoms or a phenyl group. Herein, examples of the alkyl group are the same as those specifically exemplified as the alkyl groups as R¹ and R² in the above formula (a). Among these, from the viewpoint of further improving the effect(s) by the present invention, A is preferably a linear or branched alkyl group having 1 or more and 8 or less carbon atoms, more preferably a linear or branched alkyl group having 1 or more and 3 or less carbon atoms, still more preferably a methyl group (ammonium acetate) or an ethyl group (ammonium propionate), and particularly preferably a methyl group (ammonium acetate). That is, in a preferred embodiment of the present invention, the buffer is represented by the above formula: A-COO—NH₄⁺ wherein A is a linear or branched alkyl group having 1 or more and 8 or less carbon atoms. In a more preferred embodiment of the present invention, the buffer is represented by the above formula: A-COO—NH₄⁺ wherein A is a linear or branched alkyl group having 1 or more and 3 or less carbon atoms. In a still more preferred embodiment of the present invention, the buffer is represented by the above formula: A-COO—NH₄⁺ wherein A is a methyl group or an ethyl group (the buffer is ammonium acetate or ammonium propionate) In a particularly preferred embodiment of the present invention, the component (C) (buffer) contains ammonium acetate. In a most preferred embodiment of the present invention, the component (C) (buffer) is ammonium acetate.

A content of the component (C) in the composition for surface treatment is appropriately set according to the type and the desired effect(s) of the component (C) to be used. The content of the component (C) is preferably 0.001% by mass or more, more preferably 0.005% by mass or more, and particularly preferably 0.01% by mass or more, relative to 100% by mass of the total mass of the composition for surface treatment (based on the composition for surface treatment). An upper limit of the content of the component (C) in the composition for surface treatment is preferably 0.5% by mass or less, more preferably 0.3% by mass or less, and particularly preferably 0.1% by mass or less, relative to 100% by mass of the total mass of the composition for surface treatment (based on the composition for surface treatment). In one embodiment of the present invention, the content of the component (C) is 0.001% by mass or more and 0.5% by mass or less, relative to 100% by mass of the total mass of the composition for surface treatment (based on the composition for surface treatment). In one embodiment of the present invention, the content of the component (C) is 0.005% by mass or more and 0.3% by mass or less, relative to 100% by mass of the total mass of the composition for surface treatment (based on the composition for surface treatment). In one embodiment of the present invention, the content of the component (C) is 0.01% by mass or more and 0.1% by mass or less, relative to 100% by mass of the total mass of the composition for surface treatment (based on the composition for surface treatment). When the composition for surface treatment contains two or more components (C), the content of the component (C) means the total amount thereof.

Instead of or in addition to the above, a mixing ratio between the component (A) and the component (C) in the composition for surface treatment is appropriately set according to the type and the desired effect(s) of the component (A) and the component (C) to be used. The mixing ratio of the component (A) to the component (C) (content ratio of the component (A)/the component (C)) (mass ratio) is preferably 0.01 or more, more preferably 0.1 or more, still more preferably 0.5 or more, still much more preferably more than 0.5, particularly preferably 5 or more, and most preferably 10 or more. The mixing ratio of the component (A) to the component (C) (content ratio of the component (A)/the component (C)) (mass ratio) is preferably 50 or less, more preferably 40 or less, and particularly preferably 20 or less. In one embodiment of the present invention, the mixing ratio of the component (A) to the component (C) (content ratio of the component (A)/the component (C)) (mass ratio) is 0.01 or more and 50 or less. In one embodiment of the present invention, the mixing ratio of the component (A) to the component (C) (content ratio of the component (A)/the component (C)) (mass ratio) is 0.1 or more and 40 or less. In one embodiment of the present invention, the mixing ratio of the component (A) to the component (C) (content ratio of the component (A)/the component (C)) (mass ratio) is 0.5 or more and 40 or less. In one embodiment of the present invention, the mixing ratio of the component (A) to the component (C) (content ratio of the component (A)/the component (C)) (mass ratio) is more than 0.5 and 40 or less. In one embodiment of the present invention, the mixing ratio of the component (A) to the component (C) (content ratio of the component (A)/the component (C)) (mass ratio) is 5 or more and 40 or less. In one embodiment of the present invention, the mixing ratio of the component (A) to the component (C) (content ratio of the component (A)/the component (C)) (mass ratio) is 10 or more and 20 or less. When the composition for surface treatment contains two or more components (A), the content of the component (A) means the total amount thereof. Also, when the composition for surface treatment contains two or more components (C), the content of the component (C) means the total amount thereof.

### <Component (D)>

Although the composition for surface treatment according to the present invention essentially contains the above components (A) to (C), it preferably further contains a nonionic polymer in addition to these. That is, in a preferred embodiment of the present invention, the composition for surface treatment further contains a component (D): the component (D): a nonionic polymer.

The term “nonionic polymer” as used herein refers to a polymer having neither anionic groups such as a carboxylic acid group, a sulfonic acid group, and a phosphate group, nor cationic groups such as an amino group and a quaternary ammonium group, in its molecule.

The nonionic polymer improves the wettability of the surface of the polished object, and can thus promote the removal of the residues, in particular, the organic residues on the surface of the polished object (can suppress the attachment and reattachment of organic residues and the like).

The nonionic polymer is a polymer having the same repeating structural unit (homopolymer) or different repeating structural units (copolymer), and may typically be a compound having a weight average molecular weight (Mw) of 1,000 or more. The form of the copolymer in the case where the nonionic polymer is a copolymer may be any of a block copolymer, a random copolymer, a graft copolymer, and an alternating copolymer.

Examples of the nonionic polymer include water-soluble polysaccharides such as polyvinyl alcohol, polyvinylpyrrolidone, polyacrylamide, poly N-vinyl acetamide, polyvinyl ether (e.g., polyvinyl methyl ether, polyvinyl ethyl ether, and polyvinyl isobutyl ether), polyglycerin, polyethylene glycol, polypropylene glycol, and hydroxyethyl cellulose; an alginic acid polyhydric alcohol ester, a water-soluble urea resin, a dextrin derivative, and casein. In addition, not only a polymer having such a main chain structure, but also a graft copolymer having a nonionic polymer structure in a side chain can be preferably used. Further, a copolymer such as an ethylene-vinyl alcohol copolymer or butenediol-vinyl alcohol copolymer can also be used. These nonionic polymers may be used alone or in combination of two or more.

From the viewpoint of further improving the effect of removing residues (in particular, organic residues), preferred examples of the nonionic polymer include the followings: polyvinyl alcohol, polyvinylpyrrolidone, polyacrylamide, poly N-vinyl acetamide, polyethylene glycol, hydroxyethyl cellulose, butenediol-vinyl alcohol copolymer and the like. Thus, in one embodiment, the nonionic polymer as the component (D) preferably contains at least one selected from the group consisting of polyvinyl alcohol, polyvinylpyrrolidone, polyacrylamide, poly N-vinyl acetamide, polyethylene glycol, and hydroxyethyl cellulose and butenediol-vinyl alcohol copolymer. In a still another embodiment, the nonionic polymer preferably contains at least one selected from the group consisting of polyvinyl alcohol, polyvinylpyrrolidone, and poly N-vinyl acetamide. In a still another embodiment, the nonionic polymer preferably contains polyvinyl alcohol or polyvinylpyrrolidone. In a still another embodiment, the nonionic polymer preferably contains polyvinyl alcohol. Owing to these nonionic polymers, in particular, the attachment and reattachment of organic residues are effectively suppressed, and the effect of removing residues is further improved.

A compound other than the above nonionic polymer may be contained as the component (D). From the viewpoint of further improving the effect of reducing residues, it is preferable that the component (D) be only the above nonionic polymer.

A lower limit of the weight average molecular weight (Mw) of the nonionic polymer is preferably 1,000 or more, more preferably 3,000 or more, still more preferably more than 5,000, particularly preferably 8,000 or more, and most preferably 10,000 or more. An upper limit of the weight average molecular weight (Mw) of the nonionic polymer is preferably 1,000,000 or less, more preferably 100,000 or less, still more preferably 80,000 or less, particularly preferably 50,000 or less, and most preferably less than 50,000. As one example, the weight average molecular weight (Mw) of the nonionic polymer is preferably 1,000 or more and 1,000,000 or less, more preferably 3,000 or more and 100,000 or less, still more preferably more than 5,000 and 80,000 or less, particularly preferably 8,000 or more and 50,000 or less, and most preferably 10,000 or more and less than 50,000.

The weight average molecular weight (Mw) of the nonionic polymer can be measured as a value in terms of polyethylene glycol using gel permeation chromatography (GPC), and the details of the measurement method will be described in Examples described below.

The nonionic polymer that may be used as the component (D) may be produced by synthesis, or may be a commercial product. Examples of the commercial product include JMR(R)-10HH and JMR(R)-3HH (JAPAN VAM & POVAL CO., LTD.), PITZCOL® K30A and K30L (DKS Co. Ltd.), CMC Daicel® 1150 and 1170 (Daicel Miraizu Ltd.), and GE191-104 and 107 (Showa Denko K.K.).

The nonionic polymer as the component (D) may be used alone or in combination of two or more.

A content of the component (D) in the composition for surface treatment when the composition for surface treatment contains the component (D) is appropriately set according to the type and the desired effect(s) of the component (D) to be used. The content of the component (D) is preferably 0.0001% by mass or more, more preferably 0.001% by mass or more, still more preferably 0.01% by mass or more, and particularly preferably 0.03% by mass or more, relative to 100% by mass of the total mass of the composition for surface treatment (based on the composition for surface treatment). An upper limit of the content of the component (D) in the composition for surface treatment is preferably 1.5% by mass or less, more preferably 1.0% by mass or less, still more preferably 0.5% by mass or less, and particularly preferably 0.3% by mass or less, relative to 100% by mass of the total mass of the composition for surface treatment (based on the composition for surface treatment). In one embodiment of the present invention, the content of the component (D) is 0.0001% by mass or more and 1.5% by mass or less, relative to 100% by mass of the total mass of the composition for surface treatment (based on the composition for surface treatment). In one embodiment of the present invention, the content of the component (D) is 0.001% by mass or more and 1.0% by mass or less, relative to 100% by mass of the total mass of the composition for surface treatment (based on the composition for surface treatment). In one embodiment of the present invention, the content of the component (D) is 0.01% by mass or more and 0.5% by mass or less, relative to 100% by mass of the total mass of the composition for surface treatment (based on the composition for surface treatment). In one embodiment of the present invention, the content of the component (D) is 0.03% by mass or more and 0.3% by mass or less, relative to 100% by mass of the total mass of the composition for surface treatment (based on the composition for surface treatment). When the composition for surface treatment contains two or more components (D), the content of the component (D) means the total amount thereof.

Instead of or in addition to the above, a mixing ratio between the component (A) and the component (D) in the composition for surface treatment is appropriately set according to the type and the desired effect(s) of the component (A) and the component (D) to be used. The mixing ratio of the component (A) to the component (D) (content ratio of the component (A)/the component (D)) (mass ratio) is preferably 0.01 or more, more preferably 0.05 or more, still more preferably 0.1 or more, still much more preferably more than 0.1, particularly preferably 1 or more, and most preferably 5 or more. The mixing ratio of the component (A) to the component (D) (content ratio of the component (A)/the component (D)) (mass ratio) is preferably 15 or less, more preferably 10 or less, still more preferably 5 or less, still much more preferably 3 or less, and particularly preferably less than 3. In one embodiment of the present invention, the mixing ratio of the component (A) to the component (D) (content ratio of the component (A)/the component (D)) (mass ratio) is 0.01 or more and 10 or less. In one embodiment of the present invention, the mixing ratio of the component (A) to the component (D) (content ratio of the component (A)/the component (D)) (mass ratio) is 0.05 or more and 5 or less. In one embodiment of the present invention, the mixing ratio of the component (A) to the component (D) (content ratio of the component (A)/the component (D)) (mass ratio) is 0.1 or more and 3 or less. In one embodiment of the present invention, the mixing ratio of the component (A) to the component (D) (content ratio of the component (A)/the component (D)) (mass ratio) is more than 0.1 and less than 3. In one embodiment of the present invention, the mixing ratio of the component (A) to the component (D) (content ratio of the component (A)/the component (D)) (mass ratio) is 1 or more and 15 or less. In one embodiment of the present invention, the mixing ratio of the component (A) to the component (D) (content ratio of the component (A)/the component (D)) (mass ratio) is 5 or more and 10 or less. When the composition for surface treatment contains two or more components (A), the content of the component (A) means the total amount thereof. Also, when the composition for surface treatment contains two or more components (D), the content of the component (D) means the total amount thereof.

### <pH Adjusting Agent (Component (E))>

The composition for surface treatment according to the present invention essentially contains the above components (A) to (C), and may contain the above component (D). It is preferable to further contain a pH adjusting agent, instead of the above component (D) or in addition to the above component (D). That is, in a preferred embodiment of the present invention, the composition for surface treatment further contains a component (E): the component (E): a pH adjusting agent.

The pH adjusting agent is not particularly limited, and a known pH adjusting agent that is used in the field of the composition for surface treatment can be used. A known acid, a base, or a salt thereof can be used. Examples of the pH adjusting agent include organic acids such as carboxylic acids such as formic acid, acetic acid, glycolic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, docosahexaenoic acid, eicosapentaenoic acid, lactic acid, malic acid, tartaric acid, citric acid, benzoic acid, phthalic acid, isophthalic acid, terephthalic acid, salicylic acid, gallic acid, mellitic acid, cinnamic acid, oxalic acid, malonic acid, succinic acid, glutaric acid, adipic acid, fumaric acid, maleic acid, aconitic acid, amino acid, and anthranilic acid, sulfonic acids (e.g., isethionic acid and camphorsulfonic acid), and organic phosphonic acids (e.g., hydroxyethylidene diphosphonic acid and diethylenetriamine pentamethylene phosphonic acid); inorganic acids such as nitric acid, carbonic acid, hydrochloric acid, sulfuric acid, phosphoric acid, hypophosphorous acid, phosphorus acid, phosphonic acid, boric acid, hydrofluoric acid, orthophosphoric acid, pyrophosphoric acid, metaphosphoric acid, and hexametaphosphoric acid; alkali metal hydroxides such as potassium hydrate (KOH) and sodium hydroxide (NaOH); alkali metal carbonates such as potassium carbonate (K₂CO₃) and sodium carbonate (Na₂CO₃); group 2 element hydroxides; ammonia (ammonium hydroxide); and organic bases such as quaternary ammonium hydroxide compounds. As the pH adjusting agent, a synthetic product or a commercial product may be used. These pH adjusting agents may be used alone or in combination of two or more.

Among these, when the content of the component (A) is relatively low and the pH of the composition for surface treatment is low, potassium hydrate, sodium hydroxide, sodium carbonate, or ammonia is preferable, potassium hydrate, sodium hydroxide, or ammonia is more preferable, and ammonia is particularly preferable. That is, in a preferred embodiment of the present invention, the pH adjusting agent is at least one selected from the group consisting of potassium hydrate, sodium hydroxide, sodium carbonate, and ammonia. In a more preferred embodiment of the present invention, the pH adjusting agent is at least one selected from the group consisting of potassium hydrate, sodium hydroxide, and ammonia. In a particularly preferred embodiment of the present invention, the pH adjusting agent is ammonia.

On the other hand, when the content of the component (A) is relatively high and the pH of the composition for surface treatment is high, acetic acid, sulfuric acid, nitric acid, hydrochloric acid, phosphoric acid, formic acid, propionic acid, butyric acid, oxalic acid, malonic acid, succinic acid, glutaric acid, adipic acid, maleic acid, malic acid, citric acid, glycolic acid, tartaric acid, lactic acid, or hydroxyethylidenediphosphonic acid is preferable, and acetic acid is particularly preferable.

In one embodiment of the present invention, the pH adjusting agent is ammonia or acetic acid.

As a content of the pH adjusting agent in the composition for surface treatment, it is only required to appropriately select such an amount that the desired pH value of the composition for surface treatment described in detail below is obtained.

### <pH of Composition for Surface Treatment>

A pH of the composition for surface treatment according to the present invention is more than 7.0 (the composition for surface treatment according to the present invention is alkaline). When the pH of the composition for surface treatment is 7.0 or less, the residues remaining on the surface of a polished object cannot be sufficiently removed. From the viewpoint of further improving the effect by the present invention (in particular, more efficiently removing residues), the pH of the composition for surface treatment is preferably 7.5 or more, more preferably more than 7.5, and particularly preferably 8.0 or more. The pH of the composition for surface treatment is preferably less than 12.5, more preferably 10.0 or less, still more preferably less than 10.0, still much more preferably 9.0 or less, particularly preferably less than 9.0, and most preferably less than 8.5. That is, in one embodiment of the present invention, the pH of the composition for surface treatment is 7.5 or more and less than 12.5. In one embodiment of the present invention, the pH of the composition for surface treatment is more than 7.5 and 10.0 or less. In one embodiment of the present invention, the pH of the composition for surface treatment is 8.0 or more and 10.0 or less. In one embodiment of the present invention, the pH of the composition for surface treatment is 8.0 or more and less than 10.0. In one embodiment of the present invention, the pH of the composition for surface treatment is 8.0 or more and 9.0 or less. In one embodiment of the present invention, the pH of the composition for surface treatment is 8.0 or more and less than 9.0. In one embodiment of the present invention, the pH of the composition for surface treatment is 8.0 or more and less than 8.5. As the pH of the composition for surface treatment, a value measured by the method described in Examples is employed.

### <Solvent>

The composition for surface treatment according to the present invention preferably contains a solvent. The solvent has a function of dispersing or dissolving each component. The solvent preferably contains water, and is more preferably only water. The solvent may be a mixed solvent of water and an organic solvent to disperse or dissolve each component. In this case, examples of the organic solvent to be used include acetone, acetonitrile, ethanol, methanol, isopropanol, glycerin, ethylene glycol, propylene glycol, and triethanolamine which are organic solvents to be mixed with water. Alternatively, respective components may be dispersed or dissolved by using an organic solvent without being mixed with water, and then mixed with water. These organic solvents may be used alone or in combination of two or more.

From the viewpoint of preventing the contamination on a polished object and the inhibition of the function(s) of other components, water that does not contain residues as much as possible is preferable. For example, water having a total content of transition metal ions of 100 ppb or less is preferable. Herein, purity of water can be enhanced by, for example, removing residue ions with an ion exchange resin, removing foreign materials by a filter, and an operation such as distillation. Specifically, for example, deionized water (ion exchange water), pure water, ultrapure water, or distilled water is preferably used.

### <Cyclodextrin, Cyclodextrin Derivative>

The composition for surface treatment according to the present invention may or may not further contain cyclodextrin or a cyclodextrin derivative. Herein, cyclodextrin refers to a cyclic oligosaccharide having a structural unit of glucose synthesized from starch by an enzymatic reaction. Examples thereof include α-cyclodextrin in which six glucose units are bonded together to form a cyclic structure, β-cyclodextrin in which seven glucose units are bonded together to form a cyclic structure, and γ-cyclodextrin in which eight glucose units are bonded together to form a cyclic structure. Examples of the cyclodextrin derivative include those obtained by modifying a hydroxy group in the above cyclodextrin, such as 2-hydroxypropyl-β-cyclodextrin, 2-hydroxyethyl-β-cyclodextrin and the like, and chemically modified derivatives such as methyl, propyl, monoacetyl, triacetyl, and monochlorotriazinyl derivatives.

A content of cyclodextrin and the cyclodextrin derivative in the composition for surface treatment when the composition for surface treatment contains cyclodextrin or the cyclodextrin derivative is appropriately set according to the type and the desired effect (s) of cyclodextrin or the cyclodextrin derivative to be used. The content of cyclodextrin or the cyclodextrin derivative is preferably 0.005% by mass or more, more preferably 0.01% by mass or more, and particularly preferably 0.02% by mass or more, relative to 100% by mass of the total mass of the composition for surface treatment (based on the composition for surface treatment). An upper limit of the content of cyclodextrin or the cyclodextrin derivative in the composition for surface treatment is preferably 1% by mass or less, more preferably 0.5% by mass or less, and particularly preferably 0.1% by mass or less, relative to 100% by mass of the total mass of the composition for surface treatment (based on the composition for surface treatment). With such an amount, the storage stability of the composition for surface treatment can be enhanced. When the composition for surface treatment contains two or more types of cyclodextrin or cyclodextrin derivatives, the above content means the total amount thereof. Also, when the composition for surface treatment contains cyclodextrin in combination with the cyclodextrin derivative, the above content means the total amount thereof.

### <Carboxylic Acid Compound>

The composition for surface treatment according to the present invention may or may not further contain a carboxylic acid compound.

Herein, the carboxylic acid compound is not particularly limited, as long as it has a carboxy group. Specifically, a carboxylic acid compound represented by the following formula (I) as described in WO 2021/230127 can be suitably used.

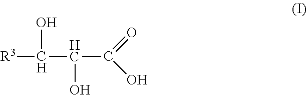

In the above formula (I), R³ is a hydrogen atom, or an alkyl group having 1 or more and 10 or less carbon atoms optionally substituted with a hydroxy group or a carboxy group. Herein, R³ may be a hydrogen atom, an unsubstituted alkyl group having 1 or more and 10 or less carbon atoms, an alkyl group having 1 or more and 10 or less carbon atoms substituted with a hydroxy group, an alkyl group having 1 or more and 10 or less carbon atoms substituted with a carboxy group, or an alkyl group having 1 or more and 10 or less carbon atoms substituted with both a hydroxy group and a carboxy group. Preferably, R³ is a hydrogen atom, or an alkyl group substituted with a hydroxy group.

Herein, examples of the alkyl group are the same as those exemplified in the above formula (a). R³ is preferably an alkyl group having 1 or more and 6 or less carbon atoms, and more preferably an alkyl group having 1 or more and 3 or less carbon atoms. The alkyl group may further have other substituents in addition to a hydroxy group or a carboxy group. Examples of other substituents include a halogen atom and an amino group.

When R³ is an alkyl group having 1 or more and 10 or less carbon atoms substituted with a hydroxy group, the number of hydroxy groups present in the alkyl group is preferably 1 or more and 10 or less, more preferably 1 or more and 5 or less, and still more preferably 2 or more and 4 or less. When R³ is an alkyl group having 1 or more and 10 or less carbon atoms substituted with a carboxy group, the number of carboxy groups present in the alkyl group is preferably 1 or more and 5 or less, more preferably 1 or more and 3 or less, and still more preferably 1 or 2.

The carboxylic acid compound of the formula (I) may be in a salt (inorganic salt or organic salt) form, but is preferably not in a salt form.

When the carboxylic acid compound of the formula (I) has a hydroxy group (R³ in the formula (I) is an alkyl group having 1 or more and 10 or less carbon atoms substituted with a hydroxy group), the number of hydroxy groups is, for example, 2 or more, and preferably 3 or more. The upper limit of the number of hydroxy groups is, for example, 10 or less, preferably 8 or less, and more preferably 5 or less.

When the carboxylic acid compound of the formula (I) has a carboxy group (R³ in the formula (I) is an alkyl group having 1 or more and 10 or less carbon atoms substituted with a carboxy group), the number of carboxy groups is preferably 2 or more. The upper limit of the number of carboxy groups is, for example, 10 or less, and preferably 5 or less. The number of carboxy groups is particularly preferably 1.

When the carboxylic acid compound of the formula (I) has both a hydroxy group and a carboxy group (R³ in the formula (I) is an alkyl group having 1 or more and 10 or less carbon atoms substituted with both a hydroxy group and a carboxy group), the ratio of the number of hydroxy groups to the number of carboxy groups [the number of hydroxy groups/the number of carboxy groups] is preferably 2 or more and 10 or less, more preferably 3 or more and 8 or less, and particularly preferably 5 or more and 6 or less.

Examples of the carboxylic acid compound of the formula (I) include gluconic acid, mucic acid, glyceric acid, and heptonic acid. Among these, gluconic acid, mucic acid, or glyceric acid is preferable, gluconic acid or mucic acid is more preferable, and gluconic acid is particularly preferable. The carboxylic acid compound of the formula (I) may be used alone or in combination of two or more.

A content of the carboxylic acid compound of the formula (I) in the composition for surface treatment when the composition for surface treatment contains the carboxylic acid compound of the formula (I) is appropriately set according to the type and the desired effect(s) of the carboxylic acid compound of the formula (I) to be used. The content of the carboxylic acid compound of the formula (I) is preferably 0.01% by mass or more, more preferably 1% by mass or more, and particularly preferably 3% by mass or more, relative to 100% by mass of the total mass of the composition for surface treatment (based on the composition for surface treatment). An upper limit of the content of the carboxylic acid compound of the formula (I) in the composition for surface treatment is preferably 10% by mass or less, more preferably 8% by mass or less, and particularly preferably 5% by mass or less, relative to 100% by mass of the total mass of the composition for surface treatment (based on the composition for surface treatment). When the composition for surface treatment contains two or more carboxylic acid compounds of the formula (I), the above content means the total amount thereof.

### <Alkanolamine Compound>

The composition for surface treatment according to the present invention may or may not further contain an alkanolamine compound. Herein, alkanolamine refers to an aliphatic compound having one or more amino groups (a primary, secondary, or tertiary amino group, preferably a primary amino group) and one or more hydroxy groups in its molecule.

As alkanolamine, for example, an alkanolamine compound represented by the following formula (II) or (III) as described in WO 2021/230127 is suitably used.

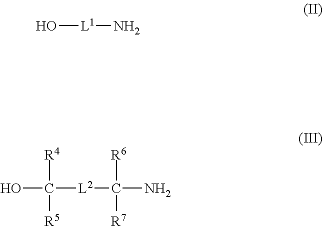

In the above formula (II), L¹ represents an alkylene group having 1 or more and 14 or less carbon atoms that may have a heteroatom. Examples of the alkylene group include linear or branched alkylene groups such as a methylene group, an ethylene group, a trimethylene group, a propylene group, a tetramethylene group, a pentamethylene group, and a hexamethylene group. In addition, examples of the substituent when the alkylene group has a heteroatom include a hydroxy group, an amino group, and a combination thereof. Among these, L¹ is preferably an unsubstituted alkylene group having 1 or more and 10 or less carbon atoms or an alkylene group having an oxygen atom and 1 or more and 10 or less carbon atoms, more preferably an unsubstituted alkylene group having 1 or more and 6 or less carbon atoms or an alkylene group having a hydroxy group and 1 or more and 6 or less carbon atoms, and particularly preferably an unsubstituted alkylene group having 1 or more and 6 or less carbon atoms. The number of hydroxy groups when L¹ is an alkylene group having a hydroxy group is preferably 1 or more and 10 or less, more preferably 1 or more and 5 or less, and particularly preferably 1 or more and 3 or less.

In the above formula (III), L² represents a single bond or an alkylene group having 1 or more and 6 or less carbon atoms that may have a heteroatom, and is preferably a single bond. Examples of the alkylene group are the same as those exemplified in the above L¹. In addition, examples of the substituent when the alkylene group has a heteroatom include a hydroxy group, an amino group, and a combination thereof. Among these, L² is preferably an unsubstituted alkylene group having 1 or more and 6 or less carbon atoms or an alkylene group having an oxygen atom and 1 or more and 6 or less carbon atoms, more preferably an unsubstituted alkylene group having 1 or more and 6 or less carbon atoms or an alkylene group having a hydroxy group and 1 or more and 6 or less carbon atoms, and particularly preferably an unsubstituted alkylene group having 1 or more and 6 or less carbon atoms.

R⁴ to R⁷ each independently represent a hydrogen atom, or a methyl group or ethyl group optionally having a substituent. In this case, R⁴ to R⁷ may be the same or different from each other. Among these, R⁴ and R⁵ are a hydrogen atom, and R⁶ and R⁷ are preferably a methyl group. R⁴ to R⁷ may have a substituent. Examples of the substituent include a hydroxy group, an amino group, and a halogen atom, and a hydroxy group is preferable.

R⁴ to R⁷ are preferably each independently a methyl group or ethyl group optionally having a hydroxy group, and more preferably an unsubstituted methyl group or ethyl group.

The alkanolamine compound represented by the above formula (II) or (III) may be an inorganic acid salt or an organic acid salt.

Specifically, examples thereof include 2-amino-2-methyl-1-propanol (AMP), trishydroxymethylaminomethane (Tris), 2-amino-2-methylpropanediol (AMPD), monoethanolamine (MEA), diethanolamine (DEA), triethanolamine (TEA), diethyleneglycolamine (DEGA), 2-(methylamino)-2-methyl-1-propanol (N-MAMP), 2-(aminoethoxy)ethanol (AEE), 2-(2-aminoethylamino) ethanol (AAE), and 2-(2-aminoethoxy)ethanol.

The above alkanolamine compound may be used alone or in combination of two or more.

A content of the alkanolamine compound in the composition for surface treatment when the composition for surface treatment contains the alkanolamine compound is appropriately set according to the type and the desired effect(s) of the alkanolamine compound to be used. The content of the alkanolamine compound is preferably 0.1% by mass or more, more preferably 0.5% by mass or more, and particularly preferably 3% by mass or more, relative to 100% by mass of the total mass of the composition for surface treatment (based on the composition for surface treatment). An upper limit of the content of the alkanolamine compound in the composition for surface treatment is preferably 10% by mass or less, and more preferably 5% by mass or less, relative to 100% by mass of the total mass of the composition for surface treatment (based on the composition for surface treatment). When the composition for surface treatment contains two or more alkanolamine compounds, the above content means the total amount thereof.

### <Surfactant>

The composition for surface treatment according to the present invention may or may not further contain a surfactant (excluding the components (A) to (E)). The type of surfactant is not particularly limited, and any of anionic, nonionic, cationic, and amphoteric surfactants may be used.

### <Chelating Agent>

The composition for surface treatment according to the present invention may or may not further contain a chelating agent. Examples of the chelating agent include an aminocarboxylic acid-based chelating agent and an organic phosphonic acid-based chelating agent.

### <Other Additives>

The composition for surface treatment according to one embodiment of the present invention may or may not contain other additives in any proportion, if necessary, within a range not inhibiting the effect (s) of the present invention. However, since components other than the essential components of the composition for surface treatment according to one embodiment of the present invention may be the cause of foreign materials (residues), it is desirable to add other components as little as possible. Thus, an amount of other additives added is preferably as low as possible. Examples of other additives include an antifungal agent (antiseptic agent), dissolved gas, a reducing agent, and an oxidizing agent. The composition for surface treatment according to the present invention contains a nonionic polymer, and is alkaline. Thus, among these, the composition for surface treatment according to the present invention preferably contains an antifungal agent (antiseptic agent). The antifungal agent (antiseptic agent) that can be used when the composition for surface treatment according to the present invention contains an antifungal agent (antiseptic agent) is not particularly limited, and can be suitably selected depending on the type of the nonionic polymer (component (B)). Specific examples thereof include isothiazolin-based antiseptic agents such as 2-methyl-4-isothiazolin-3-one, 5-chloro-2-methyl-4-isothiazolin-3-one, and 1,2-benzisothiazol-3(2H)-one (BIT), and phenoxyethanol.

In one embodiment of the present invention, the composition for surface treatment is substantially composed of a piperazine-based compound (as the component (A)), an anionic polymer (as the component (B)), a buffer (as the component (C)), and at least one selected from the group consisting of a nonionic polymer (as the component (D)), a pH adjusting agent (as the component (E)), water, an organic solvent, cyclodextrin, a cyclodextrin derivative, a carboxylic acid compound represented by the following formula (I), an alkanolamine compound, a chelating agent, a surfactant, and an antifungal agent (antiseptic agent).

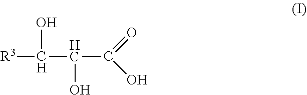

In one embodiment of the present invention, the composition for surface treatment is substantially composed of a piperazine-based compound (as the component (A)), an anionic polymer (as the component (B)), a buffer (as the component (C)), a pH adjusting agent (as the component (E)), water, and at least one selected from the group consisting of a nonionic polymer (as the component (D)), cyclodextrin, a cyclodextrin derivative, a carboxylic acid compound represented by the above formula (I), an alkanolamine compound, a chelating agent, a surfactant, and an antifungal agent (antiseptic agent).

In one embodiment of the present invention, the composition for surface treatment is substantially composed of a piperazine-based compound (as the component (A)), an anionic polymer (as the component (B)), a buffer (as the component (C)), a nonionic polymer (as the component (D)), a pH adjusting agent (as the component (E)), water, and at least one selected from the group consisting of cyclodextrin, a cyclodextrin derivative, a carboxylic acid compound represented by the above formula (I), an alkanolamine compound, a chelating agent, a surfactant, and an antifungal agent (antiseptic agent).

In one embodiment of the present invention, the composition for surface treatment is substantially composed of a piperazine-based compound (as the component (A)), an anionic polymer (as the component (B)), a buffer (as the component (C)), water, and at least one selected from the group consisting of a nonionic polymer (as the component (D)) and a pH adjusting agent (as the component (E)).

In one embodiment of the present invention, the composition for surface treatment is substantially composed of a piperazine-based compound (as the component (A)), an anionic polymer (as the component (B)), a buffer (as the component (C)), water, and at least one selected from the group consisting of a nonionic polymer (as the component (D)), a pH adjusting agent (as the component (E)), and an antifungal agent (antiseptic agent).

In one embodiment of the present invention, the composition for surface treatment is substantially composed of a piperazine-based compound (as the component (A)), an anionic polymer (as the component (B)), a buffer (as the component (C)), a nonionic polymer (as the component (D)), a pH adjusting agent (as the component (E)), and water.

In one embodiment of the present invention, the composition for surface treatment is substantially composed of a piperazine-based compound (as the component (A)), an anionic polymer (as the component (B)), a buffer (as the component (C)), a nonionic polymer (as the component (D)), a pH adjusting agent (as the component (E)), an antifungal agent (antiseptic agent), and water.

In one embodiment of the present invention, the composition for surface treatment is substantially composed of a piperazine-based compound (as the component (A)), an anionic polymer (as the component (B)), a buffer (as the component (C)), a pH adjusting agent (as the component (E)), and water.

In one embodiment of the present invention, the composition for surface treatment is substantially composed of a piperazine-based compound (as the component (A)), an anionic polymer (as the component (B)), a buffer (as the component (C)), a pH adjusting agent (as the component (E)), an antifungal agent (antiseptic agent), and water.

In the above embodiment, “the composition for surface treatment is substantially composed of X” means that a total content of X is more than 99% by mass (upper limit: 100% by mass), relative to 100% by mass of the total mass of the composition for surface treatment (based on the composition for surface treatment). Preferably, the composition for surface treatment is composed of X (the above total content=100% by mass). For example, “the composition for surface treatment is substantially composed of a piperazine-based compound (as the component (A)), an anionic polymer (as the component (B)), a buffer (as the component (C)), water, and at least one selected from the group consisting of a nonionic polymer (as the component (D)), and a pH adjusting agent (as the component (E))” means that the total content of the piperazine-based compound (as the component (A)), the anionic polymer (as the component (B)), the buffer (as the component (C)), water, the nonionic polymer (as the component (D)), and the pH adjusting agent (as the component (E)) is more than 99% by mass (upper limit: 100% by mass), relative to 100% by mass of the total mass of the composition for surface treatment (based on the composition for surface treatment). The composition for surface treatment is preferably composed of a piperazine-based compound (as the component (A)), an anionic polymer (as the component (B)), a buffer (as the component (C)), water, and at least one of a nonionic polymer (as the component (D)) and a pH adjusting agent (as the component (E)) (the above total content=100% by mass).

To further improve the effect of removing residues (foreign materials), the composition for surface treatment according to the present invention preferably does not substantially contain abrasive grains. Herein, the phrase “does not substantially contain abrasive grains” means that a content of abrasive grains is less than 0.01% by mass relative to the whole composition for surface treatment. That is, in one embodiment of the present invention, a content of abrasive grains is less than 0.01% by mass (lower limit: 0% by mass), relative to 100% by mass of the total mass of the composition for surface treatment (based on the composition for surface treatment).

### <Method for Producing Composition for Surface Treatment>

The method for producing the composition for surface treatment according to the present invention is not particularly limited, and for example, the composition for surface treatment can be obtained by stirring and mixing the component (A) (a piperazine-based compound represented by the above formula (a) and having two or more amino groups having pKa larger than the pH of the composition for surface treatment), the component (B) (an anionic polymer), the component (C) (a buffer), and other additives added as necessary. The details of each component are as described above.

In the above embodiment, the temperature at which each component is mixed is not particularly limited, and is preferably 10° C. or more and 40° C. or less. Heating may be performed to increase the rate of dissolution. The mixing time is also not particularly limited.

### [Surface Treatment Method]

According to the composition for surface treatment according to the present invention, residues (in particular, abrasive grain residues and organic residues) remaining on a surface of a polished object (in particular, a polished substrate having a nitrogen-silicon bond or containing silicon oxide) can be sufficiently removed. Thus, the present invention provides a surface treatment method including subjecting a polished object to surface treatment using the composition for surface treatment according to the present invention. The surface treatment method according to the present invention is particularly effective for the surface treatment of a polished object containing a material having a nitrogen-silicon bond (a silicon material) or silicon oxide. That is, the present invention provides a surface treatment method including subjecting a polished object containing a material having a nitrogen-silicon bond or silicon oxide to surface treatment using the composition for surface treatment according to the present invention to reduce residues on a surface of the polished object. As used herein, the term “surface treatment method” refers to a method for reducing residues on a surface of a polished object, and is a method for cleaning in a broad sense.

According to the surface treatment method according to the present invention, residues (in particular, abrasive grain residues and organic residues) remaining on a surface of a polished object (in particular, a polished substrate having a nitrogen-silicon bond or containing silicon oxide) can be sufficiently removed. That is, the present invention provides a method for reducing residues on a surface of a polished object containing a material having a nitrogen-silicon bond (a silicon material) or silicon oxide, the method including subjecting the polished object to surface treatment using the composition for surface treatment according to the present invention. In addition, the present invention provides a method for reducing at least one of abrasive grain residues and organic residues (preferably abrasive grain residues and organic residues) on a surface of a polished object containing a material having a nitrogen-silicon bond (a silicon material) or silicon oxide, the method including subjecting the polished object to surface treatment using the composition for surface treatment according to the present invention.

The surface treatment method according to the present invention is performed by directly contacting a polished object with the composition for surface treatment according to the present invention.

Mainly, examples of the surface treatment method include (I) a method by rinse polishing treatment and (II) a method by cleaning treatment. That is, in one embodiment of the present invention, the surface treatment method is a rinse polishing treatment method or a cleaning treatment method (the above surface treatment is carried out by a rinse polishing treatment or a cleaning treatment). The rinse polishing treatment and the cleaning treatment can be performed in order to remove foreign materials (e.g., abrasive grain (particle) residues, organic residues such as a polymer(s) and pad debris, metal contaminates) on a surface of a polished object and to obtain a clean surface. Hereinafter, the above (I) and (II) methods will be described.

### (I) Rinse Polishing Treatment

The composition for surface treatment according to the present invention is suitably used in rinse polishing treatment. That is, the composition for surface treatment according to the present invention can be preferably used as a rinse polishing composition. The rinse polishing treatment is performed on a polishing table (platen) equipped with a polishing pad for the purpose of removing foreign materials on a surface of a polished object after final polishing (finish polishing) is performed on an object to be polished to obtain the polished object. The rinse polishing treatment may be performed by bringing the composition for surface treatment according to the present invention into direct contact with the polished object. As a result, the foreign materials on the surface of the polished object are removed by friction force (physical action) caused by the polishing pad and chemical action caused by the composition for surface treatment. Among foreign materials, in particular, abrasive grain (particle) residues and organic residues are easily removed by the physical action. Thus, in the rinse polishing treatment, abrasive grain (particle) residues and organic residues can be effectively removed by utilizing friction with a polishing pad on a polishing table (platen). Herein, in the surface treatment using the composition for surface treatment according to the present invention, the surface of the polished object may be etched by the friction force (physical action) caused by a polishing pad and the chemical action caused by the composition for surface treatment. Moreover, abrasive grain residues and organic residues are also removed by this etching, and thus, so that the efficiency of the reduction of these residues is further improved. At this time, since the surface of the polished object is uniformly etched, the surface roughness can also be reduced.

That is, as used herein, the rinse polishing treatment, the rinse polishing method, and the rinse polishing step respectively refer to a treatment, a method, and a step of reducing a surface roughness of an object to be subjected to surface treatment and residues on the surface thereof using a polishing pad.

Specifically, the rinse polishing treatment can be performed by placing a surface of a polished object after the polishing step on a polishing table (platen) of a polishing apparatus, and relatively sliding the polished object and the polishing pad while the polishing pad and the polished object are brought into contact with each other and the composition for surface treatment is supplied to the contact portion.

As the polishing apparatus, a common polishing apparatus equipped with a holder for holding an object to be polished, a motor capable of changing the rotation number, and the like, and having a polishing table to which a polishing pad (polishing cloth) can be attached, can be used.

The rinse polishing treatment can be performed by using either a one-side polishing apparatus or a double-side polishing apparatus. The above polishing apparatus preferably has a discharge nozzle for the composition for surface treatment in addition to a discharge nozzle for a polishing composition. The operating conditions of the polishing apparatus upon the rinse polishing treatment are not particularly limited, and can be appropriately set by those skilled in the art.

As the polishing pad, common non-woven fabric, polyurethane, porous fluororesin, or the like can be used without particular limitation. The polishing pad is preferably subjected to groove processing such that the composition for surface treatment is accumulated in the grooves.

The rinse polishing conditions are also not particularly limited, and for example, the rotation number of a polishing table and the rotation number of a head (carrier) are preferably 10 rpm (0.17 s⁻¹) or more and 100 rpm (1.67 s⁻¹) or less, and a pressure applied to the polished object (polishing pressure) is preferably 0.5 psi (3.4 kPa) or more and 10 psi (68.9 kPa) or less. A method for supplying the composition for surface treatment to a polishing pad is also not particularly limited, and for example, a continuous supply method with a pump or the like (pouring) is employed. A supply amount is not limited, but preferably is such that a surface of a polishing pad is always covered with the composition for surface treatment. A supply amount is preferably 10 mL/min or more and 5000 mL/min or less. A rinse polishing time is not particularly limited, and is preferably 5 seconds or more and 180 seconds or less.

After the rinse polishing treatment by the composition for surface treatment according to the present invention, the polished object (object to be subjected to surface treatment) is preferably drawn up and taken out while the composition for surface treatment according to the present invention is applied thereto.

### (II) Cleaning Treatment

The composition for surface treatment according to the present invention may be used in cleaning treatment. That is, the composition for surface treatment according to the present invention can be preferably used as a cleaning composition. The cleaning treatment is preferably performed for the purpose of removing foreign materials on a surface of a polished object (object to be cleaned) after an object to be polished is subjected to final polishing (finish polishing) and then to the rinse polishing treatment or to another rinse polishing treatment using a composition for rinse polishing other than the composition for surface treatment according to the present invention to obtain the polished object (object to be cleaned). It should be understood that the cleaning treatment and the rinse polishing treatment are classified according to places where these treatments are performed, i.e., the cleaning treatment is performed at a place other than a polishing table (platen), and is preferably performed after a polished object is removed from a polishing table (platen). Also in the cleaning treatment, foreign materials on a surface of a polished object can be removed by bringing the composition for surface treatment according to the present invention into direct contact with the polished object.

Examples of the method of performing cleaning treatment may include: (i) a method of bringing a cleaning brush into contact with one surface or both surfaces of a polished object while holding the polished object, and rubbing the surface of an object to be cleaned with the cleaning brush while supplying the composition for surface treatment to the contact portion; (ii) a method of immersing a polished object in the composition for surface treatment, and performing ultrasonic treatment or stirring (dip method); and the like. In such a method, foreign materials on the surface of the polished object can be removed by frictional force by the cleaning brush, mechanical force generated by the ultrasonic treatment or stirring, and chemical action by the composition for surface treatment.

In the above method (i), the method for bringing the composition for surface treatment into contact with the polished object is not particularly limited, and examples thereof may include a spin method in which the polished object is rotated at a high speed while pouring the composition for surface treatment onto the polished object from a nozzle, and a spray method in which the polished object is cleaned by spraying the composition for surface treatment thereto.

From the viewpoint of more efficiently removing contamination in a short time, it is preferable to employ the spin method or the spray method for the cleaning treatment, and the spin method is more preferable.

Examples of the apparatus for performing such cleaning treatment may include a batch-type cleaning apparatus in which a plurality of polished objects accommodated in a cassette is subjected to surface treatment at the same time, and a single wafer cleaning apparatus in which one polished object is loaded on a holder and subjected to surface treatment. From the viewpoint of shortening the cleaning time, and the like, a method using a single wafer cleaning apparatus is preferable.

Further, examples of the apparatus for performing cleaning treatment may include a polishing apparatus provided with a cleaning equipment, in which a polished object is taken out from a polishing table (platen), and then the object is rubbed with a cleaning brush. By using such a polishing apparatus, the cleaning treatment of the polished object can be more efficiently performed.

As such a polishing apparatus, a common polishing apparatus having a holder for holding a polished object, a motor capable of changing the rotation number, a cleaning brush, and the like can be used. As the polishing apparatus, either a one-side polishing apparatus or a double-side polishing apparatus may be used. When the rinse polishing step is performed after a CMP step, it is more efficient and preferable that the cleaning treatment be performed by using the same apparatus as the polishing apparatus used in the rinse polishing step.

The cleaning brush is not particularly limited, and is preferably a brush made of resin. A material of the brush made of resin is not particularly limited, and PVA (polyvinyl alcohol) is preferable. The cleaning brush is more preferably a sponge made of PVA.

The cleaning conditions are also not particularly limited, and can be appropriately set depending on a type of an object to be subjected to surface treatment (polished object), and a type and amount of residues to be removed. For example, the rotation number of the cleaning brush is preferably 10 rpm (0.17 s⁻¹) or more and 200 rpm (3.33 s⁻¹) or less, and the rotation number of the object to be cleaned is preferably 10 rpm (0.17 s⁻¹) or more and 100 rpm (1.67 s⁻¹) or less. The method for supplying the composition for surface treatment to the cleaning brush is also not particularly limited, and for example, a continuous supply method using a pump or the like (pouring) is employed. The amount supplied is not limited, but preferably is such that a surface of the cleaning brush and an object to be cleaned are always covered with the composition for surface treatment, and is preferably 10 mL/min or more and 5000 mL/min or less. A cleaning time is also not particularly limited, and the step using the composition for surface treatment according to one embodiment of the present invention is preferably 5 seconds or more and 180 seconds or less. Within such a range, the foreign materials can be further effectively removed.

A temperature of the composition for surface treatment upon cleaning is not particularly limited, and may typically be room temperature. However, the temperature may be warmed to about 40° C. or more and 70° C. or less within a range of not impairing the performance.

In the above method (ii), conditions in the cleaning method by immersion are not particularly limited, and a known method can be used.

Cleaning with water may be performed before the surface treatment is performed by the above method (I) or (II).

### (Post-Cleaning Treatment)

As the surface treatment method, the polished object is preferably further subjected to cleaning treatment after the surface treatment in the (I) or (II) using the composition for surface treatment according to the present invention. As used herein, this cleaning treatment is referred to as the “post-cleaning treatment”. The post-cleaning treatment is not particularly limited, and examples thereof may include a method in which water is simply poured onto an object to be subjected to surface treatment and a method in which an object to be subjected to surface treatment is simply immersed in water. Similarly to the surface treatment by the method (II) as described above, examples of the post-cleaning treatment may include a method (brush cleaning) of bringing a cleaning brush into contact with one surface or both surfaces of an object to be subjected to surface treatment while holding the object to be subjected to surface treatment, and rubbing a surface of the object to be subjected to surface treatment with the cleaning brush while supplying water or an aqueous solution (for example, NH₃ aqueous solution) to a contact portion therebetween, or supplying water and an aqueous solution (for example, NH₃ aqueous solution) to the contact portion in any order (supplying water and then supplying the aqueous solution or supplying the aqueous solution and then supplying water), a method (dip method) of immersing an object to be subjected to surface treatment in water and performing ultrasonic treatment or stirring, and the like. Among these methods, a method of bringing a cleaning brush into contact with one surface or both surfaces of an object to be subjected to surface treatment with the object to be subjected to surface treatment in a held state, and rubbing a surface of the object to be subjected to surface treatment with the cleaning brush while supplying water or an aqueous solution (for example, NH₃ aqueous solution) to a contact portion therebetween, or supplying water and an aqueous solution (for example, NH₃ aqueous solution) to the contact portion in any order (supplying water and then supplying the aqueous solution or supplying the NH₃ aqueous solution and then supplying water) is preferably used. As an apparatus and conditions of the post-cleaning treatment, the description of the surface treatment of (II) described above can be referred to. Herein, deionized water is particularly preferably used as water used in the post-cleaning treatment.

By performing surface treatment with the composition for surface treatment according to one embodiment of the present invention, residues are brought into a significantly easy-to-remove state. Thus, residues can be significantly well removed by performing surface treatment using the composition for surface treatment according to the surface treatment of one embodiment of the present invention and then performing further cleaning treatment using water.

### [Method for Producing Semiconductor Substrate]

The surface treatment method according to the present invention is suitably applied when the polished object is a polished semiconductor substrate. That is, the present invention also provides a method for producing a semiconductor substrate, in which a polished object is a polished semiconductor substrate, the method including reducing residues on a surface of the polished semiconductor substrate by the above surface treatment method.

The polished object preferably contains at least one of a material containing a nitrogen-silicon bond (silicon material) and silicon oxide. That is, the present invention also is to provide a method for producing a semiconductor substrate, in which a polished object is a polished semiconductor substrate, the method including: a polishing step of polishing a semiconductor substrate before polishing containing a material having a nitrogen-silicon bond or silicon oxide using a polishing composition containing abrasive grains to obtain a polished semiconductor substrate, and a surface treatment step of subjecting the polished semiconductor substrate to surface treatment using the composition for surface treatment according to the present invention.

The details of the semiconductor substrate to which such a production method is applied are as in the description for the polished object which is subjected to surface treatment using the above composition for surface treatment.

The method for producing a semiconductor substrate is not particularly limited, as long as it includes a step of subjecting a surface of a polished semiconductor substrate to surface treatment using the composition for surface treatment according to the present invention (surface treatment step). Examples of such a production method may include a method including a polishing step for forming a polished semiconductor substrate and a cleaning step. Another example is a method including a rinse polishing step between the polishing step and the cleaning step in addition to the polishing step and the cleaning step. Hereinafter, each of these steps will be described.

### <Polishing Step>

The polishing step that may be included in the method for producing a semiconductor substrate is a step of polishing a semiconductor substrate to obtain a polished semiconductor substrate.

The polishing step is not particularly limited, as long as it is a step of polishing a semiconductor substrate, and is preferably a chemical mechanical polishing (CMP) step. The polishing step may be a polishing step composed of a single step or may be a polishing step composed of a plurality of steps. Examples of the polishing step composed of a plurality of steps may include a step of performing a finish polishing step after a preliminary polishing step (rough polishing step), and a step of performing one or two or more secondary polishing step (s) after a primary polishing step, and then performing a finish polishing step. The surface treatment step using the composition for surface treatment according to the present invention is preferably performed after the above finish polishing step.

As the polishing composition, a known polishing composition can be appropriately used depending on characteristics of the semiconductor substrate. The polishing composition is not particularly limited, and examples thereof may include a polishing composition containing abrasive grains, a water-soluble polymer, a pH adjusting agent, and a solvent, and the like.

As the polishing apparatus, a common polishing apparatus equipped with a holder for holding an object to be polished, a motor capable of changing the rotation number, and the like, and having a polishing table to which a polishing pad (polishing cloth) can be attached, can be used. As the polishing apparatus, either a one-side polishing apparatus or a double-side polishing apparatus may be used.

### <Surface Treatment Step>

The surface treatment step refers to a step of reducing residues on a surface of a polished object using the composition for surface treatment according to the present invention. In the method for producing a semiconductor substrate, a cleaning step as the surface treatment step may be performed after a rinse polishing step, or only a rinse polishing step or only a cleaning step may be performed.

### (Rinse Polishing Step)

The rinse polishing step may be provided between the polishing step and the cleaning step, in the method for producing a semiconductor substrate. The rinse polishing step is a step of reducing foreign materials on a surface of a polished object (polished semiconductor substrate) by the surface treatment method (rinse polishing treatment method) according to one embodiment of the present invention.

The details of the rinse polishing method used in the rinse polishing step are as described in the description according to the above (I) rinse polishing treatment.

### (Cleaning Step)

The cleaning step may be provided after the polishing step or after the rinse polishing step, in the method for producing a semiconductor substrate. The cleaning step is a step of reducing foreign materials on a surface of a polished object (polished semiconductor substrate) by the surface treatment method (the cleaning method) according to one embodiment of the present invention.

The details of the cleaning method used in the cleaning step are the same as in the above (post-cleaning treatment).

The embodiments of the present invention have been described in detail, but they are exemplary and illustrative purposes and not restrictive, and it is apparent that the scope of the present invention should be interpreted by the claims.

The present invention includes the following aspects and embodiments.

1. A composition for surface treatment including components (A) to (C) below, wherein pH of the composition is more than 7.0:
the component (A): a piperazine-based compound represented by formula (a) below and having two or more amino groups having pKa larger than the pH of the composition for surface treatment,

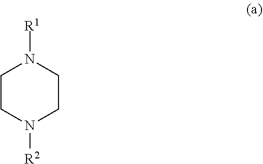

wherein R¹ is a hydrogen atom, or an alkyl group having 1 or more and 10 or less carbon atoms optionally substituted with any of primary to tertiary amino groups; and R² is an alkyl group having 1 or more and 10 or less carbon atoms optionally substituted with any of primary to tertiary amino groups,
the component (B): an anionic polymer, and
the component (C): a buffer represented by a formula: A-COO—NH₄⁺, wherein A is an alkyl group having 1 or more and 10 or less carbon atoms or a phenyl group.

2. The composition for surface treatment according to the above 1., wherein the component (A) contains a piperazine-based compound represented by the above formula (a), wherein R¹ is a hydrogen atom, or an alkyl group having 1 or more and 5 or less carbon atoms optionally substituted with a primary or tertiary amino group; and R² is an alkyl group having 1 or more and 5 or less carbon atoms optionally substituted with a primary or tertiary amino group.

3. The composition for surface treatment according to the above 1. or 2., wherein the component (A) contains a piperazine-based compound represented by the above formula (a), wherein R¹ is a hydrogen atom, or an alkyl group having 1 or more and 3 or less carbon atoms optionally substituted with a primary or tertiary amino group; and R² is an alkyl group having 1 or more and 3 or less carbon atoms substituted with a primary amino group.

4. The composition for surface treatment according to any of the above 1. to 3., wherein a content of the component (A) is 0.10% or more relative to the composition for surface treatment.

5. The composition for surface treatment according to any of the above 1. to 4., wherein the component (A) has an amino group having a difference between a maximum pKa in the pKa's of the amino groups present in the piperazine-based compound (maximum pKa) and the pH of the composition for surface treatment (=maximum pKa−pH) of 0.5 or more.

6. The composition for surface treatment according to any of the above 1. to 5., wherein the component (A) has an amino group having a difference between a maximum pKa in the pKa's of the amino groups present in the piperazine-based compound (maximum pKa) and the pH of the composition for surface treatment (=maximum pKa−pH) of more than 1.30.

7. The composition for surface treatment according to any of the above 1. to 6., wherein the component (B) contains at least one anionic polymer selected from the group consisting of poly(meth)acrylic acid, polystyrene sulfonic acid, and poly(carboxylic acid-sulfonic acid), and salts thereof.

8. The composition for surface treatment according to any of the above 1. to 7., wherein the component (C) contains ammonium acetate.

9. The composition for surface treatment according to any of the above 1. to 8., further containing a component (D):
the component (D): a nonionic polymer.

10. The composition for surface treatment according to the above 9., wherein the component (D) contains at least one nonionic polymer selected from the group consisting of polyvinyl alcohol, polyvinylpyrrolidone, polyacrylamide, poly N-vinyl acetamide, polyethylene glycol, hydroxyethyl cellulose, and butenediol-vinyl alcohol copolymer.

11. The composition for surface treatment according to any of the above 1. to 10., further containing a component (E):
the component (E): a pH adjusting agent.

12. The composition for surface treatment according to the above 11., wherein the pH adjusting agent is ammonia or acetic acid.

13. The composition for surface treatment according to any of the above 1. to 8., wherein the composition for surface treatment is substantially composed of the component (A), the component (B), the component (C), water, and at least one selected from the group consisting of a pH adjusting agent and a nonionic polymer.

14. The composition for surface treatment according to any of the above 1. to 8., wherein the composition for surface treatment is substantially composed of the component (A), the component (B), the component (C), water, and at least one selected from the group consisting of a pH adjusting agent, a nonionic polymer, and an antifungal agent (antiseptic agent).

15. The composition for surface treatment according to any of the above 1. to 8., wherein the composition for surface treatment is substantially composed of the component (A), the component (B), the component (C), a nonionic polymer, a pH adjusting agent, and water.

16. The composition for surface treatment according to any of the above 1. to 8., wherein the composition for surface treatment is substantially composed of the component (A), the component (B), the component (C), a nonionic polymer, a pH adjusting agent, an antifungal agent (antiseptic agent), and water.

17. The composition for surface treatment according to any of the above 1. to 8., wherein the composition for surface treatment is substantially composed of the component (A), the component (B), the component (C), a pH adjusting agent, and water.

18. The composition for surface treatment according to any of the above 1. to 8., wherein the composition for surface treatment is substantially composed of the component (A), the component (B), the component (C), a pH adjusting agent, an antifungal agent (antiseptic agent), and water.

19. A surface treatment method, including subjecting a polished object containing a material having a nitrogen-silicon bond or silicon oxide to surface treatment using the composition for surface treatment set forth in any of the above 1. to 18. to reduce a residue on a surface of the polished object.

20. The surface treatment method according to the above 19., wherein the surface treatment is carried out by a rinse polishing treatment or a cleaning treatment.

21. The surface treatment method according to the above 19. or 20., wherein the residue contains at least one of an abrasive grain residue and an organic residue.

22. A method for producing a semiconductor substrate, wherein a polished object is a polished semiconductor substrate,
the method including:
polishing a semiconductor substrate before polishing containing a material having a nitrogen-silicon bond or silicon oxide using a polishing composition containing an abrasive grain to obtain a polished semiconductor substrate, and
subjecting the polished semiconductor substrate to surface treatment using the composition for surface treatment set forth in the above 1. to 18.

### Examples

The present invention will be described further in detail by way of the following Examples and Comparative Examples. However, the technical scope of the present invention is not limited to the following Examples only. Unless otherwise indicated, “%” and “part” mean “% by mass” and “part by mass”, respectively. In the following Examples, unless otherwise indicated, operations were performed under the conditions of room temperature (25° C.)/relative humidity of 40% RH or more and 50% RH or less.

### [Preparation of Components (A) to (E)]

The following components (A) to (E) were prepared.

### <Component (A): Piperazine-Based Compound>

Aminoethylpiperazine (in the formula (a), R¹=H, R²=an aminoethyl group (—CH₂CH₂NH₂)) (manufactured by Tokyo Chemical Industry Co., Ltd., product name: N-(2-aminoethyl)piperazine; molecular weight=129; pKa=10.11, 8.78, 1.74)
1,4-bis(3-Aminopropyl) piperazine (in the formula (a), R¹, R²=an aminopropyl group (—CH₂CH₂CH₂NH₂)) (manufactured by Tokyo Chemical Industry Co., Ltd., product name: 1,4-bis(3-aminopropyl)piperazine; molecular weight=200; pKa=10.69, 10.09, 6.50, 2.37)
1-Ethylpiperazine (in the formula (a), R¹=H, R²=an ethyl group (—CH₂CH₃)) (manufactured by Tokyo Chemical Industry Co., Ltd., product name: 1-ethylpiperazine; molecular weight=114; pKa=9.27, 8.13)
1-(2-Dimethylaminoethyl)-4-methylpiperazine (in the formula (a), R¹=a methyl group (—CH₃), R²=a dimethylaminoethyl group (—CH₂CH₂N(CH₃)₂)) (manufactured by Tokyo Chemical Industry Co., Ltd., product name: 1-(2-dimethylaminoethyl)-4-methylpiperazine; molecular weight=171; pKa=9.50, 9.20, 8.17)

### <Component (A′): Other Amine Compounds>

Piperazine anhydrous (in the formula (a), R¹, R²=H) (manufactured by Tokyo Chemical Industry Co., Ltd. product name: piperazine anhydrous; molecular weight=86; pKa=9.55, 5.30)
1-Amino-4-methylpiperazine (in the formula (a), R¹=a methyl group (—CH₃), R²=a primary amino group (—NH₂)) (manufactured by Tokyo Chemical Industry Co., Ltd., product name: 1-amino-4-methylpiperazine; molecular weight=115; pKa=7.64, 7.19, 6.80)

### <Component (B): Anionic Polymer>

Polyacrylic acid (manufactured by TOAGOSEI CO., LTD., product name: JURYMER AC-10SH; weight average molecular weight (Mw)=1,000,000) (polyacrylic acid 1)
Polyacrylic acid (manufactured by TOAGOSEI CO., LTD. product name: JURYMER AC-10L; weight average molecular weight (Mw)=20,000 to 30,000) (polyacrylic acid 2)
Polyacrylic acid (manufactured by TOAGOSEI CO., LTD. product name: ARON A-10H; weight average molecular weight (Mw)=200,000) (polyacrylic acid 3)
Sodium polystyrene sulfonate (manufactured by Tosoh Finechem Corporation, product name: PolyNaSS PS-1; weight average molecular weight (Mw)=20,000)
Copolymer of carboxylic acid and sulfonic acid (sodium salt) (manufactured by TOAGOSEI CO., LTD., product name: ARON A-6012; weight average molecular weight (Mw)=10,000)

### <Component (C): pH Buffer>

Ammonium acetate (manufactured by Kanto Chemical Co., Inc.; molecular weight: 77)

### <Component (D): Nonionic Polymer>

Polyvinyl alcohol (PVA) (manufactured by JAPAN VAM & POVAL CO., LTD., product name: JMR®-10HH; weight average molecular weight (Mw)=10,000)

### <Component (E): pH Adjusting Agent>

Ammonia (manufactured by Kanto Chemical Co., Inc., product name: EL Ammonia solution; molecular weight: 17)
Acetic acid (manufactured by Kanto Chemical Co., Inc., product name: acetic acid; molecular weight: 60)

The weight average molecular weights (Mw) of the above component (B) and component (D) were measured by the following method.

### [Measurement of Weight Average Molecular Weight (Mw)]

As the weight average molecular weights (Mw) of the component (B) and the component (D), the values of the weight average molecular weights (in terms of polyethylene glycol) measured by gel permeation chromatography (GPC) were used. The weight average molecular weight was measured by the following apparatus and under the following conditions:
GPC apparatus: manufactured by SHIMADZU CORPORATION
Model name: Prominence+ELSD detector (ELSD-LTII)
Column: VP-ODS (manufactured by SHIMADZU CORPORATION)
Mobile phase A: MeOH
   B: 1% aqueous acetic acid solution
Flow rate: 1 mL/min
Detector: ELSD temp. 40° C., Gain 8, N₂ GAS 350 kPa
Oven temperature: 40° C.
Injection volume: 40 μL.

### [Measurement of pH of Composition for Surface Treatment]

pH of the composition for surface treatment (liquid temperature: 25° C.) was confirmed by a pH meter (manufactured by Horiba, Ltd., product name: LAQUA®). pH of the polishing composition described below was measured by the same method.

### [Preparation of Composition for Surface Treatment]

### Example 1

Aminoethylpiperazine as the component (A), polyacrylic acid (Mw=1,000,000) as the component (B), ammonium acetate as the component (C), polyvinyl alcohol (Mw=10,000) as the component (D), ammonia as the component (E), and distilled water as a solvent were stirred and mixed at 25° C. for 5 minutes to prepare a composition for surface treatment 1.

Herein, the content of each component was as follows: a content of the component (A) was 0.03% by mass (0.3 g/L), a content of the component (B) was 0.01% by mass (0.1 g/L), a content of the component (C) was 0.03% by mass (0.3 g/L), a content of the component (D) was 0.06% by mass (0.6 g/L), and a content of the component (E) (pH adjusting agent) was set to an amount such that pH of the composition for surface treatment 1 was 8.0, relative to the total amount of the composition for surface treatment 1.

### Examples 2 to 24, Comparative Examples 1 to 20

Compositions for surface treatment 2 to 24 and comparative compositions for surface treatment 1 to 20 were prepared in the same manner as in Example 1, except that the component (A)/(A′), the component (B), the component (C), the component (D), the component (E), and the pH were each changed as described in Table 1. Although Comparative Example 20 was adjusted to have pH of 8 upon preparation, the pH value after the adjustment was lowered with time. The stable performance of the composition for surface treatment was determined to be not successfully exerted, and the examination was stopped (no cleaning data). In Table 1, “-” indicates that the corresponding component was not added.

The compositions for surface treatment 1 to 24 and the comparative compositions for surface treatment 1 to 19 prepared above do not contain abrasive grains (content of abrasive grains=0% by mass).

The composition of each composition for surface treatment is summarized in Table 1 below. In Table 1 below, the item “pKa” shows pKa values of the amino groups present in the component (A) or the component (A′), and the pKa larger than the pH of each composition for surface treatment is underlined. In Table 1 below, when the difference between a pKa value of an amino group present in the component (A) or the component (A′) and the pH of each composition for surface treatment (=pKa−pH) is positive, the difference is expressed numerically as “pKa−pH”. When the above difference (=pKa−pH) is 0 or less, it is expressed as “-”.

TABLE 1

| | Component (A)/(A′) | | | Component (B) | | Component (C) | |
|---|---|---|---|---|---|---|---|
| | | Content | | | Content | | Content |
| | | [% by | | | [% by | | [% by |
| | Compound | mass] | pKa | Compound | mass] | Buffer | mass) |
| Example 1 | Aminoethyl- | 0.03 | 10.11 | Polyacrylic | 0.01 | Ammonium | 0.03 |
| | piperazine | | 8.78 | acid 1 | | acetate | |
| | | | 1.74 | | | | |
| Comperative | Aminoethyl- | 0.03 | 10.11 | Polyacrylic | 0.01 | Ammonium | 0.03 |
| Example 1 | piperazine | | 8.78 | acid 1 | | acetate | |
| | | | 1.74 | | | | |
| Comparative | Aminoethyl- | 0.03 | 10.11 | Polyacrylic | 0.01 | Ammonium | 0.03 |
| Example 2 | piperazine | | 8.78 | acid 1 | | acetate | |
| | | | 1.74 | | | | |
| Example 2 | 1,4-bis(3- | 0.03 | 10.69 | Polyacrylic | 0.01 | Ammonium | 0.03 |
| | Aminopropyl) | | 10.09 | acid 1 | | acetate | |
| | piperazine | | 6.50 | | | | |
| | | | 2.37 | | | | |
| Example 3 | 1,4-bis(3- | 0.03 | 10.69 | Polyacrylic | 0.01 | Ammonium | 0.03 |
| | Aminopropyl) | | 10.09 | acid 1 | | acetate | |
| | piperazine | | 6.50 | | | | |
| | | | 2.37 | | | | |
| Example 4 | 1,4-bis(3- | 0.03 | 10.69 | Polyacrylic | 0.01 | Ammonium | 0.03 |
| | Aminopropyl) | | 10.09 | acid 1 | | acetate | |
| | piperazine | | 6.50 | | | | |
| | | | 2.37 | | | | |
| Comparative | Piperazine | 0.03 | 9.55 | Polyacrylic | 0.01 | Ammonium | 0.03 |
| Example 3 | anhydrous | | 5.30 | acid 1 | | acetate | |
| Comparative | Piperazine | 0.03 | 9.55 | Polyacrylic | 0.01 | Ammonium | 0.03 |
| Example 4 | anhydrous | | 5.30 | acid 1 | | acetate | |
| Comparative | Piperazine | 0.03 | 9.55 | Polyacrylic | 0.01 | Ammonium | 0.03 |
| Example 5 | anhydrous | | 5.30 | acid 1 | | acetate | |
| Comparative | 1-Amino-4-methyl- | 0.03 | 7.64 | Polyacrylic | 0.01 | Ammonium | 0.03 |
| Example 6 | piperazine | | 7.19 | acid 1 | | acetate | |
| | | | 6.80 | | | | |
| Comparative | 1-Amino-4-methyl- | 0.03 | 7.64 | Polyacrylic | 0.01 | Ammonium | 0.03 |
| Example 7 | piperazine | | 7.19 | acid 1 | | acetate | |
| | | | 6.80 | | | | |
| Comparative | 1-Amino-4-methyl- | 0.03 | 7.64 | Polyacrylic | 0.01 | Ammonium | 0.03 |
| Example 8 | piperazine | | 7.19 | acid 1 | | acetate | |
| | | | 6.80 | | | | |
| Example 5 | 1-Ethylpiperazine | 0.03 | 9.27 | Polyacrylic | 0.01 | Ammonium | 0.03 |
| | | | 8.13 | acid 1 | | acetate | |
| Comparative | 1-Ethylpiperazine | 0.03 | 9.27 | Polyacrylic | 0.01 | Ammonium | 0.03 |
| Example 9 | | | 8.13 | acid 1 | | acetate | |
| Comparative | 1-Ethylpiperazine | 0.03 | 9.27 | Polyacrylic | 0.01 | Ammonium | 0.03 |
| Example 10 | | | 8.13 | acid 1 | | acetate | |
| Example 6 | 1-(2-Dimethyl- | 0.03 | 9.50 | Polyacrylic | 0.01 | Ammonium | 0.03 |
| | aminoethyl)-4- | | 9.20 | acid 1 | | acetate | |
| | methylpiperazine | | 8.17 | | | | |
| Example 7 | 1-(2-Dimethyl- | 0.03 | 9.50 | Polyacrylic | 0.01 | Ammonium | 0.03 |
| | aminoethyl)-4- | | 9.20 | acid 1 | | acetate | |
| | methylpiperazine | | 8.17 | | | | |
| Comparative | 1-(2-Dimethyl- | 0.03 | 9.50 | Polyacrylic | 0.01 | Ammonium | 0.03 |
| Example 11 | aminoethyl)-4- | | 9.20 | acid 1 | | acetate | |
| | methylpiperazine | | 8.17 | | | | |
| Comparative | Aminoethyl- | 0.03 | 10.11 | — | — | Ammonium | 0.03 |
| Example 12 | piperazine | | 8.78 | | | acetate | |
| | | | 1.74 | | | | |
| Comparative | Aminoethyl- | 0.03 | 10.11 | — | — | Ammonium | 0.03 |
| Example 13 | piperazine | | 8.78 | | | acetate | |
| | | | 1.74 | | | | |
| Comparative | Aminoethyl- | 0.03 | 10.11 | — | — | Ammonium | 0.03 |
| Example 14 | piperazine | | 8.78 | | | acetate | |
| | | | 1.74 | | | | |
| Example 12 | Aminoethyl- | 0.13 | 10.11 | Polyacrylic | 0.01 | Ammonium | 0.03 |
| | piperazine | | 8.78 | acid 2 | | acetate | |
| | | | 1.74 | | | | |
| Example 13 | Aminoethyl- | 0.13 | 10.11 | Polyacrylic | 0.01 | Ammonium | 0.03 |
| | piperazine | | 8.78 | acid 2 | | acetate | |
| | | | 1.74 | | | | |
| Example 14 | Aminoethyl- | 0.13 | 10.11 | Sodium | 0.01 | Ammonium | 0.03 |
| | piperazine | | 8.78 | polystyrene | | acetate | |
| | | | 1.74 | sulfonate | | | |
| Example 15 | Aminoethyl- | 0.13 | 10.11 | Copolymer of | 0.01 | Ammonium | 0.03 |
| | piperazine | | 8.78 | carboxylic acid | | acetate | |
| | | | 1.74 | and sulfonic acid | | | |
| | | | | (sodium salt) | | | |
| Example 16 | Aminoethyl- | 0.26 | 10.11 | Polyacrylic | 0.01 | Ammonium | 0.03 |
| | piperazine | | 8.78 | acid 2 | | acetate | |
| | | | 1.74 | | | | |
| Example 17 | Aminoethyl- | 0.52 | 10.11 | Polyacrylic | 0.005 | Ammonium | 0.03 |
| | piperazine | | 8.78 | acid 2 | | acetate | |
| | | | 1.74 | | | | |
| Example 18 | Aminoethyl- | 0.52 | 10.11 | Polyacrylic | 0.01 | Ammonium | 0.03 |
| | piperazine | | 8.78 | acid 2 | | acetate | |
| | | | 1.74 | | | | |
| Example 19 | Aminoethyl- | 0.52 | 10.11 | Polyacrylic | 0.02 | Ammonium | 0.03 |
| | piperazine | | 8.78 | acid 2 | | acetate | |
| | | | 1.74 | | | | |
| Example 20 | Aminoethyl- | 0.52 | 10.11 | Polyacrylic | 0.01 | Ammonium | 0.03 |
| | piperazine | | 8.78 | acid 2 | | acetate | |
| | | | 1.74 | | | | |
| Example 21 | Aminoethyl- | 1.04 | 10.11 | Polyacrylic | 0.01 | Ammonium | 0.03 |
| | piperazine | | 8.78 | acid 2 | | acetate | |
| | | | 1.74 | | | | |
| Example 22 | Aminoethyl- | 0.52 | 10.11 | Polyacrylic | 0.01 | Ammonium | 0.03 |
| | piperazine | | 8.78 | acid 3 | | acetate | |
| | | | 1.74 | | | | |
| Example 23 | Aminoethyl- | 0.52 | 10.11 | Polyacrylic | 0.01 | Ammonium | 0.03 |
| | piperazine | | 8.78 | acid 1 | | acetate | |
| | | | 1.74 | | | | |
| Example 24 | Aminoethyl- | 0.52 | 10.11 | Polyacrylic | 0.02 | Ammonium | 0.03 |
| | piperazine | | 8.78 | acid 1 | | acetate | |
| | | | 1.74 | | | | |

| | Component (D) | | | | |
|---|---|---|---|---|---|
| | | Content | Component (E) | Physical | |
| | | [% by | pH Adjusting | property | |
| | Compound | mass] | agent | pH | pKa − pH |
| Example 1 | Polyvinyl alcohol | 0.06 | Ammonia | 8.0 | 2.11 |
| | | | | | 0.78 |
| | | | | | — |
| Comperative | Polyvinyl alcohol | 0.06 | Ammonia | 9.0 | 1.11 |
| Example 1 | | | | | — |
| | | | | | — |
| Comparative | Polyvinyl alcohol | 0.06 | Ammonia | 10.0 | 0.11 |
| Example 2 | | | | | — |
| | | | | | — |
| Example 2 | Polyvinyl alcohol | 0.06 | Ammonia | 8.0 | 2.69 |
| | | | | | 2.09 |
| | | | | | — |
| | | | | | — |
| Example 3 | Polyvinyl alcohol | 0.06 | Ammonia | 9.0 | 1.69 |
| | | | | | 1.09 |
| | | | | | — |
| | | | | | — |
| Example 4 | Polyvinyl alcohol | 0.06 | Ammonia | 10.0 | 0.69 |
| | | | | | 0.09 |
| | | | | | — |
| | | | | | — |
| Comparative | Polyvinyl alcohol | 0.06 | Ammonia | 8.0 | 1.55 |
| Example 3 | | | | | — |
| Comparative | Polyvinyl alcohol | 0.06 | Ammonia | 9.0 | 0.55 |
| Example 4 | | | | | — |
| Comparative | Polyvinyl alcohol | 0.06 | Ammonia | 10.0 | — |
| Example 5 | | | | | — |
| Comparative | Polyvinyl alcohol | 0.06 | Ammonia | 8.0 | — |
| Example 6 | | | | | — |
| | | | | | — |
| Comparative | Polyvinyl alcohol | 0.06 | Ammonia | 9.0 | — |
| Example 7 | | | | | — |
| | | | | | — |
| Comparative | Polyvinyl alcohol | 0.06 | Ammonia | 10.0 | — |
| Example 8 | | | | | — |
| | | | | | — |
| Example 5 | Polyvinyl alcohol | 0.06 | Ammonia | 8.0 | 1.27 |
| | | | | | 0.13 |
| Comparative | Polyvinyl alcohol | 0.06 | Ammonia | 9.0 | 0.27 |
| Example 9 | | | | | — |
| Comparative | Polyvinyl alcohol | 0.06 | Ammonia | 10.0 | — |
| Example 10 | | | | | — |
| Example 6 | Polyvinyl alcohol | 0.06 | Ammonia | 8.0 | 1.50 |
| | | | | | 1.20 |
| | | | | | 0.17 |
| Example 7 | Polyvinyl alcohol | 0.06 | Ammonia | 9.0 | 0.50 |
| | | | | | 0.20 |
| | | | | | — |
| Comparative | Polyvinyl alcohol | 0.06 | Ammonia | 10.0 | — |
| Example 11 | | | | | — |
| | | | | | — |
| Comparative | Polyvinyl alcohol | 0.06 | Ammonia | 8.0 | 2.11 |
| Example 12 | | | | | 0.78 |
| | | | | | — |
| Comparative | Polyvinyl alcohol | 0.06 | Ammonia | 9.0 | 1.11 |
| Example 13 | | | | | — |
| | | | | | — |
| Comparative | Polyvinyl alcohol | 0.06 | Ammonia | 10.0 | 0.11 |
| Example 14 | | | | | — |
| | | | | | — |
| Example 12 | Polyvinyl alcohol | 0.09 | Acetic acid | 8.0 | 2.11 |
| | | | | | 0.78 |
| | | | | | — |
| Example 13 | — | — | Acetic acid | 8.0 | 2.11 |
| | | | | | 0.78 |
| | | | | | — |
| Example 14 | Polyvinyl alcohol | 0.09 | Acetic acid | 8.0 | 2.13 |
| | | | | | 0.78 |
| | | | | | — |
| Example 15 | Polyvinyl alcohol | 0.09 | Acetic acid | 8.0. | 2.11 |
| | | | | | 0.78 |
| | | | | | — |
| Example 16 | Polyvinyl alcohol | 0.09 | Acetic acid | 8.0 | 2.11 |
| | | | | | 0.78 |
| | | | | | — |
| Example 17 | Polyvinyl alcohol | 0.09 | Acetic acid | 8.0 | 2.11 |
| | | | | | 0.78 |
| | | | | | — |
| Example 18 | Polyvinyl alcohol | 0.09 | Acetic acid | 8.0 | 2.11 |
| | | | | | 0.78 |
| | | | | | — |
| Example 19 | Polyvinyl alcohol | 0.09 | Acetic acid | 8.0 | 2.11 |
| | | | | | 0.78 |
| | | | | | — |
| Example 20 | Polyvinyl alcohol | 0.09 | Acetic acid | 8.5 | 1.61 |
| | | | | | 0.28 |
| | | | | | — |
| Example 21 | Polyvinyl alcohol | 0.09 | Acetic acid | 8.0 | 2.11 |
| | | | | | 0.78 |
| | | | | | — |
| Example 22 | Polyvinyl alcohol | 0.09 | Acetic acid | 8.0 | 2.11 |
| | | | | | 0.78 |
| | | | | | — |
| Example 23 | Polyvinyl alcohol | 0.09 | Acetic acid | 8.0 | 2.11 |
| | | | | | 0.78 |
| | | | | | — |
| Example 24 | Polyvinyl alcohol | 0.09 | Acetic acid | 8.0 | 2.11 |
| | | | | | 0.78 |
| | | | | | — |

### [Evaluation 1]

The number of defects (the number of abrasive grain residues and the number of organic residues) on the silicon nitride (Si₃N₄) substrate were measured by the following method, and the results are shown in Table 2 below. In Table 2 below, the total number of the number of abrasive grain residues and the number of organic residues is described as the “total number”.

### [Preparation of Polished Object]

Polished objects after being polished by the following chemical mechanical polishing (CMP) step (polished silicon nitride substrate) were provides.

### (CMP Step)

As objects to be polished, a silicon wafer having a silicon nitride film with a thickness of 2500 Å was formed on the surface thereof by CVD (silicon nitride substrate) (300 mm, blanket wafer, manufactured by ADVANTEC CO., LTD.) and a silicon wafer having a TEOS film with a thickness of 10000 Å was formed on the surface thereof (TEOS substrate) (300 mm, blanket wafer, manufactured by ADVANTEC CO., LTD.) were provided.

A silica slurry (composition: 10% by mass of colloidal silica (average primary particle size: 35 nm, average secondary particle size: 70 nm), 0.25% by mass of polyvinylpyrrolidone (PITZCOL® K30A, DKS Co. Ltd., Mw=45,000), 0.33% by mass (as NH₃) of EL aqueous ammonia (concentration: 28.0% to 30.0% (as NH₃) (Kanto Chemical Co., Inc.), solvent: distilled water) was prepared. The above silica slurry was diluted to 5 times with distilled water to prepare a polishing composition. pH of the obtained polishing composition was 10.0.

The silicon nitride substrate and the TEOS substrate prepared above were polished using the polishing composition obtained above under the following conditions to obtain a polished object (polished silicon nitride substrate and polished TEOS substrate).

### <Polishing Apparatus and Polishing Conditions>

Polishing apparatus: FREX300E manufactured by Ebara Corporation
Polishing pad: foamed polyurethane pad manufactured by FUJIBO HOLDINGS, INC.
   H800-Type 1
Conditioner (dresser): nylon brush (manufactured by 3M Company)
Polishing pressure: 2.0 psi (1 psi=6894.76 Pa, the same applies hereinafter)
Rotation number of polishing table: 80 rpm
Rotation number of head: 80 rpm
Supply of polishing composition: continuously pouring without recycle Amount of polishing composition supplied: 200 mL/min
Polishing time: 30 seconds.

### (Rinse Polishing)

After each surface of the object to be polished was polished in the above CMP step, the polished object was taken out from the polishing table (platen). Subsequently, the polished object was attached onto another polishing table (platen) in the same polishing apparatus, and a surface of the polished object was subjected to rinse polishing treatment using each of the compositions for surface treatment (compositions for surface treatment 1 to 24 and comparative compositions for surface treatment 1 to 19) under the following conditions.

### <Rinse Polishing Apparatus and Rinse Polishing Conditions>

Polishing apparatus: FREX300E manufactured by Ebara Corporation
Polishing pad: foamed polyurethane pad manufactured by FUJIBO HOLDINGS, INC.
   H800-Type1
Conditioner (dresser): nylon brush (manufactured by 3M Company)
Polishing pressure: 1.0 psi
Rotation number of table: 80 rpm
Rotation number of head: 80 rpm
Supply of composition for surface treatment: continuously pouring without recycle
Amount of composition for surface treatment supplied: 300 mL/min
Polishing time: 60 seconds.

### (Post-Cleaning Treatment)

After the rinse polishing treatment, a surface of the polished object was subjected to brush cleaning for 20 seconds using a 0.3% NH₃ aqueous solution, and then cleaned for 40 seconds with deionized water to obtain each rinse-polished object (rinse-polished objects 1 to 24 and comparative rinse-polished objects 1 to 19).

### (Residue Evaluation)

The number of residues on the surface of each rinse-polished object (rinse-polished objects 1 to 24 and comparative rinse-polished objects 1 to 19) was evaluated using an optical inspection device Surfscan® SP5 manufactured by KLA-Tencor Corporation.

Specifically, the number of residues having a diameter of more than 70 nm (when the polished object is a silicon nitride substrate) and the number of residues having a diameter of more than 50 nm (when the polished object is a TEOS substrate) were counted on the remaining portion excluding a portion having a width of 5 mm from the outer peripheral edge (when the outer peripheral edge is set to 0 mm, the region from 0 mm to 5 mm) on one surface of each rinse-polished object. Thereafter, regarding each rinse-polished object described above, the number of abrasive grain residues and the number of organic residues were measured by SEM observation using Review SEM RS6000 manufactured by Hitachi High-Tech Corporation. First, 100 residues existing in the remaining portion excluding the portion having a width of 5 mm from the outer peripheral edge on one surface of each rinse-polished object were sampled in the SEM observation. Then, the type of residues (abrasive grains or organic residues) was determined by visual SEM observation from among sampled 100 residues, and the number of abrasive grain residues (SiO₂ residues) and the number of organic residues (pad debris, polymer(s), and the like) were respectively measured.

The number of abrasive grain residues (SiO₂ residues) is preferably as low as possible. As one example, when the polished object is a silicon nitride substrate, the number of abrasive grain residues (SiO₂ residues) is acceptably less than 50, preferably 45 or less, more preferably less than 35, still more preferably 30 or less, and particularly preferably 25 or less. When the polished object is a TEOS substrate, the number of abrasive grain residues (SiO₂ residues) is acceptably less than 2480, preferably 2400 or less, more preferably 2200 or less, still more preferably 2000 or less, and particularly preferably 1500 or less.

Also, the number of organic residues (such as pad debris and polymers) is preferably as low as possible. As one example, when the polished object is a silicon nitride substrate, the number of organic residues (such as pad debris, polymer(s) and the like) is acceptably less than 20, preferably 10 or less, more preferably 5 or less, and particularly preferably 3 or less. When the polished object is a TEOS substrate, the number of organic residues (such as pad debris, polymer(s) and the like) is acceptably 30 or less, preferably 25 or less, more preferably 20 or less, and particularly preferably 15 or less.

Further, the total number of the number of abrasive grain residues (SiO₂ residues) and the number of organic residues (such as pad debris, polymer (s) and the like) (the “total number” in Table 2) is also preferably as low as possible. As one example, when the polished object is a silicon nitride substrate, the total number of the number of abrasive grain residues (SiO₂ residues) and the number of organic residues (such as pad debris, polymer(s) and the like) is acceptably 75 or less, preferably 60 or less, more preferably 35 or less, and particularly preferably 27 or less. When the polished object is a TEOS substrate, the total number of the number of abrasive grain residues (SiO₂ residues) and the number of organic residues (such as pad debris, polymer(s) and the like) is acceptably less than 2990, preferably 2800 or less, more preferably 2600 or less, and particularly preferably 2000 or less.

### [Evaluation 2]

An amount of adsorption of the components contained in the composition for surface treatment was measured by the following method, and the results are shown in Table 2 below (“Si₃N₄ Amount of adsorption [ng/cm²]” or “TEOS Amount of adsorption [ng/cm²]” in Table).

### (Measurement of Amount of Adsorption by QCM Method)

An amount of adsorption of the components contained in the composition for surface treatment on the silicon nitride (Si₃N₄) surface or the TEOS surface was measured using a quartz crystal microbalance method (QCM method). For the measurement, a QCM-D measurement apparatus Q-Sense-Pro (manufactured by ALTECH Co., Ltd.) was used.

The measurement procedure is as follows. First, 180 μL of pure water was set in the measurement apparatus and stabilized at 25° C. Thereafter, each composition for surface treatment was allowed to flow at a flow rate of 20 μL/min for 5 minutes, and the amount of adsorption (ng/cm²) of the components contained in the composition for surface treatment on the Si₃N₄ electrode surface or TEOS electrode surface (per unit area) was measured.

As described above, it is presumed that, when the composition for surface treatment according to the present invention is used, the component (A) and the component (B) are adsorbed to a substrate surface, so that the effect of reducing residues can be obtained. A large amount of adsorption of the components contained in the composition for surface treatment indicates that the component (A) and the component (B) are easily adsorbed to a substrate surface. Thus, a large numerical value shown in the above measurement of the amount of adsorption is considered to support the presumption that the component (A) and the component (B) act as in the above mechanism.

### [Evaluation 3]

Zeta potential (ζ potential) of silicon nitride (Si₃N₄) in each composition for surface treatment was measured by the following method, and the results are shown in Table 2 below (“Si₃N₄ zeta potential [mV]” in Table).

Using each composition for surface treatment, zeta potential of silicon nitride (Si₃N₄) during rinse polishing was set to the value measured in the model experiment as described below.

For the measurement of the zeta potential, a silicon wafer having a silicon nitride film with a thickness of 2500 Å was formed on the surface thereof by CVD (silicon nitride substrate) (300 mm blanket wafer, manufactured by ADVANTEC CO., LTD.) was cut into a 60 mm square, which was used as the object to be measured. The above object to be measured was installed on SurPASS3 (zeta potential meter) which is a solid zeta potential measuring instrument manufactured by Anton Paar Japan K.K. Then, each composition for surface treatment prepared above was made to flow over the object to be measured, and zeta potential (mV) of the object to be measured was measured.

TABLE 2

| | | | | Number of defects on Si₃N₄ substrate (>70 nm) | | | Number of defects on TEOS substrate (>50 nm) | | |
|---|---|---|---|---|---|---|---|---|---|
| | Si₃N₄ | | TEOS | | Number of | Number of | | Number of | Number of |
| | Amount of | Zeta | Amount of | Total | abrasive grain | organic | Total | abrasive grain | organic |
| | adsorption | potential | adsorption | number | residues | residues | number | residues | residues |
| | [ng/cm²] | [mV] | [ng/cm²] | [count] | [count] | [count] | [count] | [count] | [count] |
| Example 1 | 198 | −37 | 200 | 22 | 21 | 1 | 2576 | 2137 | 27 |
| Comparative | 63 | −15 | 62 | 93 | 88 | 5 | 3450 | 2862 | 36 |
| Example 1 | | | | | | | | | |
| Comparative | 56 | −16 | 56 | 98 | 92 | 6 | 3300 | 2737 | 35 |
| Example 2 | | | | | | | | | |
| Example 2 | 211 | −35 | 200 | 18 | 17 | 1 | 2576 | 2137 | 27 |
| Example 3 | 205 | −32 | 199 | 26 | 24 | 2 | 2781 | 2307 | 29 |
| Example 4 | 199 | −34 | 200 | 41 | 35 | 6 | 2138 | 1773 | 22 |
| Comparative | 72 | −14 | 72 | 83 | 79 | 4 | 2990 | 2480 | 31 |
| Example 3 | | | | | | | | | |
| Comparative | 77 | −16 | 80 | 82 | 79 | 3 | 3001 | 2489 | 31 |
| Example 4 | | | | | | | | | |
| Comparative | 53 | −18 | 50 | 87 | 82 | 5 | 3555 | 2949 | 37 |
| Example 5 | | | | | | | | | |
| Comparative | 43 | −15 | 40 | 93 | 91 | 2 | 3590 | 2978 | 38 |
| Example 6 | | | | | | | | | |
| Comparative | 36 | −15 | 40 | 95 | 86 | 9 | 3300 | 2737 | 35 |
| Example 7 | | | | | | | | | |
| Comparative | 21 | −12 | 24 | 89 | 84 | 5 | 3887 | 3224 | 41 |
| Example 8 | | | | | | | | | |
| Example 5 | 182 | −31 | 188 | 41 | 33 | 8 | 2741 | 2274 | 29 |
| Comparative | 69 | −18 | 69 | 85 | 82 | 3 | 3221 | 2672 | 34 |
| Example 9 | | | | | | | | | |
| Comparative | 38 | −14 | 37 | 90 | 84 | 6 | 3981 | 3302 | 42 |
| Example 10 | | | | | | | | | |
| Example 6 | 226 | −32 | 210 | 29 | 26 | 3 | 2454 | 2035 | 26 |
| Example 7 | 219 | −35 | 205 | 53 | 43 | 10 | 2514 | 2085 | 26 |
| Comparative | 52 | −15 | 50 | 93 | 88 | 5 | 3612 | 2996 | 38 |
| Example 11 | | | | | | | | | |
| Comparative | 17 | −11 | 20 | 141 | 103 | 38 | 3971 | 3294 | 42 |
| Example 12 | | | | | | | | | |
| Comparative | 21 | −9 | 22 | 143 | 99 | 44 | 3887 | 3224 | 41 |
| Example 13 | | | | | | | | | |
| Comparative | 29 | −10 | 34 | 142 | 106 | 36 | 3678 | 3051 | 38 |
| Example 14 | | | | | | | | | |
| Comparative | 19 | −8 | 22 | 172 | 125 | 47 | 3910 | 3243 | 41 |
| Example 15 | | | | | | | | | |
| Comparative | 17 | −11 | 15 | 162 | 133 | 29 | 4201 | 3485 | 44 |
| Example 16 | | | | | | | | | |
| Comparative | 15 | −12 | 15 | 151 | 121 | 30 | 4119 | 3417 | 43 |
| Example 17 | | | | | | | | | |
| Example 8 | 151 | −30 | 160 | 32 | 25 | 7 | 2872 | 2372 | 26 |
| Comparative | 12 | −19 | 14 | 93 | 84 | 9 | 4429 | 3674 | 46 |
| Example 18 | | | | | | | | | |
| Comparative | 15 | −14 | 15 | 99 | 90 | 9 | 4421 | 3667 | 46 |
| Example 19 | | | | | | | | | |
| Example 9 | 164 | −30 | 280 | 27 | 20 | 7 | 1840 | 1527 | 19 |
| Example 10 | 172 | −31 | 182 | 37 | 27 | 10 | 2831 | 2349 | 30 |
| Example 11 | 166 | −32 | 158 | 46 | 35 | 11 | 2843 | 2320 | 29 |
| Example 12 | 334 | −5 | 140 | 19 | 18 | 1 | 2730 | 2291 | 30 |
| Example 13 | 373 | −5 | 380 | 23 | 20 | 3 | 1578 | 1309 | 17 |
| Example 14 | 321 | −3 | 310 | 22 | 20 | 2 | 1551 | 1287 | 16 |
| Example 15 | 207 | −7 | 220 | 23 | 21 | 2 | 2342 | 1943 | 25 |
| Exemple 16 | 459 | −10 | 466 | 18 | 17 | 1 | 1106 | 917 | 12 |
| Example 17 | 523 | −2 | 543 | 18 | 17 | 1 | 1112 | 922 | 12 |
| Exemple 18 | 539 | +1 | 539 | 16 | 15 | 1 | 956 | 793 | 10 |
| Example 19 | 563 | −1 | 577 | 15 | 13 | 2 | 761 | 631 | 8 |
| Example 20 | 437 | ND | 444 | 20 | 19 | 1 | 1544 | 1281 | 16 |
| Example 21 | 629 | ND | 642 | 16 | 15 | 1 | 901 | 747 | 9 |
| Example 22 | 890 | ND | 899 | 16 | 15 | 1 | 573 | 475 | 6 |
| Example 23 | 1058 | +1 | 1059 | 15 | 14 | 1 | 410 | 340 | 4 |
| Example 24 | 1053 | −2 | 1049 | 14 | 12 | 2 | 491 | 407 | 5 |

As is apparent from Table 2 above, it is understood that, according to the compositions for surface treatment of Examples, the residues on the silicon nitride substrate and the TEOS substrate can be sufficiently removed as compared with the compositions for surface treatment of Comparative Examples.

In addition, from each comparison between Example 1 and Example 8, Comparative Example 1 and Comparative Example 18, Comparative Example 2 and Comparative Example 19, Examples 2 to 4 and Examples 9 to 11, and Example 12 and Example 13, it can be understood that the presence of polyvinyl alcohol to be present as the component (D) can significantly reduce the number of organic residues.

The above results are the results evaluated immediately after the production of the composition for surface treatment, but the composition for surface treatment preferably contains an antifungal agent (antiseptic agent) when the composition is stored or stocked for a long term. Since an antifungal agent (antiseptic agent) has almost no effect or has no effect on the above results, the composition for surface treatment containing the antifungal agent (antiseptic agent) is considered to also have the same results as above.

1. A composition for surface treatment comprising components (A) to (C) below, wherein pH of the composition is more than 7.0:
the component (A): a piperazine-based compound represented by a formula (a) below and having two or more amino groups having pKa larger than the pH of the composition for surface treatment: 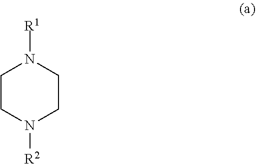
wherein R¹ is a hydrogen atom, or an alkyl group having 1 or more and 10 or less carbon atoms optionally substituted with any of primary to tertiary amino groups; and R² is an alkyl group having 1 or more and 10 or less carbon atoms optionally substituted with any of primary to tertiary amino groups,
the component (B): an anionic polymer, and
the component (C): a buffer represented by a formula: A-COO—NH₄⁺, wherein A is an alkyl group having 1 or more and 10 or less carbon atoms or a phenyl group.

2. The composition for surface treatment according to claim 1, wherein the component (A) comprises a piperazine-based compound represented by the formula (a), wherein R¹ is a hydrogen atom, or an alkyl group having 1 or more and 5 or less carbon atoms optionally substituted with a primary or tertiary amino group; and R² is an alkyl group having 1 or more and 5 or less carbon atoms optionally substituted with a primary or tertiary amino group.

3. The composition for surface treatment according to claim 1, wherein the component (A) comprises a piperazine-based compound represented by the formula (a), wherein R¹ is a hydrogen atom, or an alkyl group having 1 or more and 3 or less carbon atoms optionally substituted with a primary or tertiary amino group; and R² is an alkyl group having 1 or more and 3 or less carbon atoms substituted with a primary amino group.

4. The composition for surface treatment according to claim 1, wherein a content of the component (A) is 0.10% by mass or more relative to the composition for surface treatment.

5. The composition for surface treatment according to claim 1, wherein the component (A) has an amino group having a difference between a maximum pKa in the pKa′ s of the amino groups present in the piperazine-based compound (maximum pKa) and the pH of the composition for surface treatment (=maximum pKa−pH) of 0.5 or more.

6. The composition for surface treatment according to claim 1, wherein the component (A) has an amino group having a difference between a maximum pKa in the pKa′ s of the amino groups present in the piperazine-based compound (maximum pKa) and the pH of the composition for surface treatment (=maximum pKa−pH) of more than 1.30.

7. The composition for surface treatment according to claim 1, wherein the component (B) comprises at least one anionic polymer selected from the group consisting of poly(meth)acrylic acid, polystyrene sulfonic acid, and poly(carboxylic acid-sulfonic acid), and salts thereof.

8. The composition for surface treatment according to claim 1, wherein the component (C) comprises ammonium acetate.

9. The composition for surface treatment according to claim 1, further comprising a component (D):
the component (D): a nonionic polymer.

10. The composition for surface treatment according to claim 9, wherein the component (D) comprises at least one nonionic polymer selected from the group consisting of polyvinyl alcohol, polyvinylpyrrolidone, polyacrylamide, poly N-vinyl acetamide, polyethylene glycol, hydroxyethyl cellulose, and butenediol-vinyl alcohol copolymer.

11. The composition for surface treatment according to claim 1, further comprising a component (E):
the component (E): a pH adjusting agent.

12. The composition for surface treatment according to claim 11, wherein the pH adjusting agent is ammonia or acetic acid.

13. The composition for surface treatment according to claim 1, wherein the composition for surface treatment is substantially composed of the component (A), the component (B), the component (C), water, and at least one selected from the group consisting of a pH adjusting agent and a nonionic polymer.

14. A surface treatment method, comprising subjecting a polished object containing a material having a nitrogen-silicon bond or silicon oxide to surface treatment using the composition for surface treatment set forth in claim 1, to reduce a residue on a surface of the polished object.

15. The surface treatment method according to claim 14, wherein the surface treatment is carried out by a rinse polishing treatment or a cleaning treatment.

16. The method according to claim 14, wherein the residue comprises at least one of an abrasive grain residue and an organic residue.

17. A method for producing a semiconductor substrate, wherein a polished object is a polished semiconductor substrate,
the method comprising:
polishing a semiconductor substrate before polishing containing a material having a nitrogen-silicon bond or silicon oxide using a polishing composition containing an abrasive grain to obtain a polished semiconductor substrate, and
subjecting the polished semiconductor substrate to surface treatment using the composition for surface treatment set forth in claim 1.
